(19) United States
(12) Patent Application Publication
(10) Pub. No.: US 2023/0387643 A1
(43) Pub. Date: Nov. 30, 2023

(54) LASER EMISSION MODULE AND LIDAR

(71) Applicant: SUTENG INNOVATION TECHNOLOGY CO., LTD., Shenzhen (CN)

(72) Inventors: Ying LIANG, Shenzhen (CN); Wenmin ZHU, Shenzhen (CN)

(73) Assignee: SUTENG INNOVATION TECHNOLOGY CO., LTD., Shenzhen (CN)

(21) Appl. No.: 18/200,536

(22) Filed: May 22, 2023

(30) Foreign Application Priority Data
May 25, 2022 (CN) 202210573095.0
May 31, 2022 (CN) 202210611023.0

(51) Int. Cl. H01S 3/04; H01S 3/10

(52) U.S. Cl. CPC H01S 3/0405; H01S 3/10038; G01S 7/4814

(57) ABSTRACT

This application discloses a laser emission module and a LIDAR. The laser emission module includes: a laser emitter, a heat conduction substrate including a first board surface, and a first support board including a third board surface facing toward the laser emitter. The first board surface is configured to connect the laser emitter. The third board surface has a mounting region. The heat conduction substrate corresponding to the mounting region is mounted on the first support board.

### CROSS-REFERENCE TO RELATED APPLICATION

The present application claims the benefit of priority to China Patent Application No. CN 202210573095.0, filed on May 25, 2022, and China Patent Application No. CN 202210611023.0, filed on May 31, 2022, the contents of which are incorporated herein by references in their entireties.

### TECHNICAL FIELD

This application relates to the field of LiDAR technologies, and in particular, to a laser emission module and a LiDAR.

### BACKGROUND

A laser emission module includes a laser emitter and an emission board. The laser emitter is disposed on the emission board, the laser emitter with high power consumption generates a large amount of heat during working, and if the heat cannot be transmitted in a timely manner, normal working of the laser emitter will be affected. Therefore, how to effectively transmit the heat of the laser emitter to ensure the normal working of the laser emitter has become a problem that urgently needs to be resolved.

### SUMMARY

Embodiments of this application provide a laser emission module and a LiDAR, which can effectively transmit heat generated by a laser emitter or an emission chip during working to ensure normal working of the laser emitter.

According to a first aspect, an embodiment of this application provides a laser emission module, where the laser emission module includes: a laser emitter; a heat conduction substrate, including a first board surface, where the first board surface is configured to connect the laser emitter; and a first support board, including a third board surface facing toward the laser emitter, where the third board surface is provided with a mounting region, and the heat conduction substrate corresponding to the mounting region is mounted on the first support board.

Based on the laser emission module in the embodiments of this application, the heat conduction substrate is designed to absorb the heat generated by the laser emitter during working, and therefore, the heat generated by the laser emitter during working can be quickly transmitted to the heat conduction substrate, and then the heat conduction substrate quickly transmits the heat to the first support board or a heat dissipation structure, so that the heat is not accumulated on the laser emitter, thereby ensuring performance and efficiency of the laser emitter during working for long time. The heat conduction substrate is disposed corresponding to the mounting region of the first support board, and only a heat conduction substrate having a size close to that of the laser emitter is required to achieve a good heat dissipation effect on the laser emitter without a need to use the heat conduction substrate for the entire first support board, thereby reducing an overall volume and production costs of the laser emission module.

According to a second aspect, an embodiment of this application provides a LiDAR, where the LiDAR includes the forgoing laser emission module.

Based on the LiDAR in the embodiments of this application, the LiDAR having the foregoing laser emission module can transmit the heat generated by the laser emitter in a timely manner during working, and therefore, has a good heat dissipation effect, thereby effectively improving detection performance of the LIDAR

According to a third aspect, an embodiment of this application provides a LiDAR, where the LiDAR includes the foregoing laser emission module and a heat dissipation structure, the heat dissipation structure includes a housing, the housing has an accommodating cavity, the laser emission module is disposed in the accommodating cavity, and the heat conduction substrate comes into contact with a part of an inner wall surface of the housing via the first heat conduction element, and transmits heat directly to the housing through the first heat conduction element; or
the heat dissipation structure includes a housing and a heat guiding mechanism, the housing has an accommodating cavity, the laser emission module and the heat guiding mechanism are both disposed in the accommodating cavity, and the heat guiding mechanism comes into contact with the heat conduction substrate via the first heat conduction element, absorbs heat from the heat conduction substrate, and guides the absorbed heat to a preset heat dissipation region of the housing.

Based on the LiDAR in the embodiments of this application, the LiDAR having the foregoing laser emission module and the foregoing heat dissipation structure directly transmits heat to the housing via the first heat conduction element, or transmits the heat to the first heat conduction element and then indirectly transmits the heat to the preset heat dissipation region of the housing via the heat guiding mechanism during working, which can transmit the heat generated by the laser emitter in a timely manner and therefore, achieves a good heat dissipation effect, thereby effectively improving detection performance of the LiDAR

A fourth aspect of this application provides a laser emission apparatus, including:
a ceramic carrier;
a laser emission chip, affixed to the ceramic carrier; and
a circuit board, spaced or partially overlapped with the ceramic carrier and electrically connected to the laser emission chip to control the laser emission chip to emit a laser beam.

Based on the laser emission apparatus provided above, the laser emission chip is affixed to the ceramic carrier to utilize the larger thermal conductivity coefficient of the ceramic carrier so that the heat generated by the laser emission chip can be discharged in a timely manner to improve the working stability of the laser emission chip.

A fifth aspect of this application provides LiDAR, where the LiDAR includes a housing and the forgoing laser emission apparatus. The housing has a light-transmitting region, the laser beam emitted by the laser emission chip is emitted to the outside of the housing via the light-transmitting region.

Based on the forgoing embodiment, the laser emission apparatus is mounted in the housing. The housing, on the one hand, provides a location for mounting and fixing the laser emission apparatus, and on the other hand, isolates the laser emission apparatus from the outside world to avoid damage to the laser emission apparatus caused by an external factor so as to protect the laser emission apparatus. Further, the laser emission chip of the laser emission apparatus is mounted in the ceramic carrier. By utilizing the larger thermal conductivity coefficient of the ceramic carrier, the heat generated by the ceramic carrier can be discharged in a timely manner, thus ensuring the operation stability of the LiDAR.

Based on the laser emission apparatus of an embodiment of this application, the laser emission chip is affixed to the ceramic carrier, and utilizes the larger thermal conductivity coefficient of the ceramic carrier so that the heat generated by the laser emission chip is discharged in a timely manner, thus improving the operational stability of the laser emission chip. When the circuit board and the ceramic carrier are arranged at intervals, the laser emission chip can be completely mounted in the ceramic carrier to ensure the heat dissipation needs of the laser emission chip. The circuit board does not contact with the ceramic carrier, thus reducing the use amount of the ceramic carrier to save costs. Further, the circuit board can also be partially overlapped with the ceramic carrier to achieve contact. The temperature inside the laser emission apparatus is reduced, thus providing a more suitable operation environment for the laser emission chip so as to improve the operation stability of the laser emission chip.

### BRIEF DESCRIPTION OF DRAWINGS

To describe the technical solutions in the embodiments of this application or in the prior art more clearly, the following briefly describes the accompanying drawings. Apparently, the accompanying drawings in the following description show merely some embodiments of this application, and a person skilled in the art may still derive other drawings from these accompanying drawings without creative efforts.

FIG. 1 is a schematic cross-sectional view of a laser emission module in a related art;

FIG. 2 is a schematic cross-sectional view of a laser emission module according to an embodiment of this application;

FIG. 3 is a schematic cross-sectional view of a laser emission module according to another embodiment of this application;

FIG. 4 is a schematic cross-sectional view of a laser emitter and a heat conduction substrate connected via a first heat conduction member according to an embodiment of this application;

FIGS. 5a-5d are schematic cross-sectional views of a laser emitter and a heat conduction substrate connected via a first binding member and a second heat conduction member according to an embodiment of this application;

FIG. 6 is a schematic diagram of a circuit structure of a two-dimensional laser device array according to an embodiment of this application;

FIG. 7 is a schematic structural diagram of an electrical connection between a laser emitter and a first support board according to an embodiment of this application:

FIG. 8 is a schematic cross-sectional view of a first support board according to an embodiment of this application;

FIG. 9 is a schematic cross-sectional view of a laser emission module according to an embodiment of this application;

FIG. 10 is a schematic cross-sectional view of a laser emission module and a part of a heat dissipation structure according to an embodiment of this application;

FIG. 11 is a schematic cross-sectional view of a laser emission module and a part of a heat dissipation structure according to another embodiment of this application;

FIG. 12 is a schematic cross-sectional view of a first support board and a heat conduction substrate before assembly according to another embodiment of this application;

FIG. 13 is a schematic cross-sectional view of a laser emission module according to another embodiment of this application:

FIG. 14 is a schematic cross-sectional view of LiDAR according to an embodiment of this application;

FIG. 15 is a schematic cross-sectional view of LiDAR according to another embodiment of this application;

FIG. 16 is a schematic structural diagram of a laser emission apparatus according to one embodiment of this application;

FIG. 17 is a schematic structural diagram of a laser emission apparatus (a circuit board and a ceramic carrier are arranged at intervals) according to one embodiment of this application; and

FIG. 18 is a schematic structural diagram of a laser emission apparatus (a circuit board is opened and provided with an avoidance hole) according to one embodiment of this application;

FIG. 19 is a schematic structural diagram of a ceramic carrier according to one embodiment of this application; and

FIG. 20 is a schematic structural diagram of a LiDAR according to one embodiment of this application.

Reference signs: 1′—laser emission module; 11′—laser emitter; and 12′—circuit board; and
1—laser emission module; 11—laser emitter; 111—positive electrode addressable drive circuit; 1111—positive electrode addressing drive circuit; 1112—another circuit; 112—negative electrode addressable drive circuit; 1121—negative electrode addressing drive circuit; 113—two-dimensional laser device array; 1131—laser diode; 12—heat conduction substrate; 121—connection portion; 122—restrictive portion; 123—first board surface: 124—second board surface; 125—abutment structure; 13—first support board; 131—third board surface; 1311—mounting region; 13111—mounting surface: 13112—recess; 13113—through hole; 13114—first sub-hole; 13115—second sub-hole; 13116—stepped structure; 13117—first hole segment; 13118—second hole segment; 13119—restrictive structure; M—hole axis; 132—fourth board surface; 14—wire; 141—first end: 142—second end; 15—first heat conduction member; 161—first binding member; 162—second heat conduction member; 2—LiDAR; 21—heat dissipation structure: 211—housing; 2111—accommodating cavity: 2112—preset heat dissipation region; 212—heat guiding mechanism; 22—first heat conduction element; 23—convex structure; and 24—second heat conduction element.
3—ceramic carrier; 31—insulating substrate; 311—first electrically conductive part; 312—second electrically conductive part; 32—mounting surface: 4—laser emission chip: 41—light beam: 42—light output surface: 5—circuit board: 51—avoidance hole; 6—wire; 7—heat dissipation support member; 70—metal board; 71—bearing surface; 72—mounting groove: 73—metal boss; 8—housing: 81—light-transmitting region.

### DETAILED DESCRIPTION

To make the objectives, technical solutions, and advantages of this application more comprehensible, the following further describes this application in detail with reference to accompanying drawings and embodiments. It should be understood that the specific embodiments described herein are merely used to explain this application but are not intended to limit this application.

A laser emission module includes a laser emitter and a circuit board. The laser emitter is integrated on the circuit board, the laser emitter with high power consumption generates a large amount of heat during working, and if the heat cannot be transmitted in a timely manner, detection performance of the laser emitter will be affected.

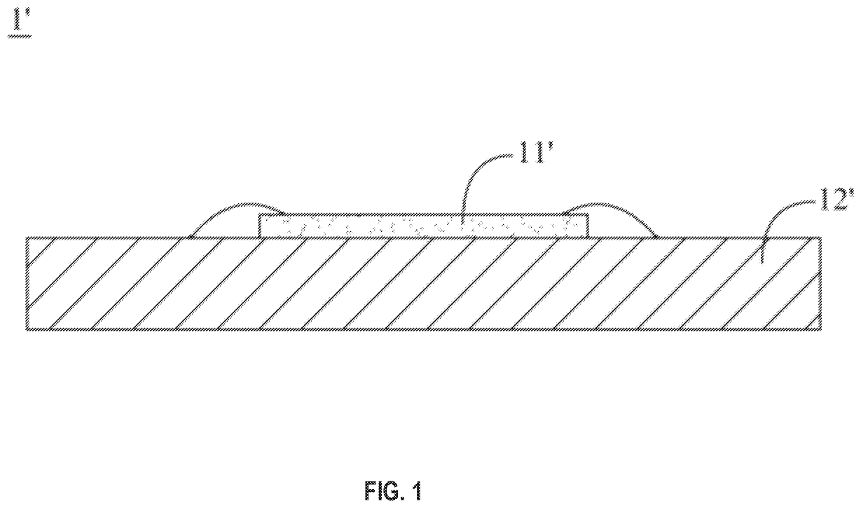

For example, as shown in FIG. 1, in related art, a laser emission module 1′ includes a laser emitter 11′ and a circuit board 12′, the laser emitter 11′ is integrated on the circuit board 12′, and a preparation material of the circuit board 12′ includes an FR4 material. Because the laser emitter 11′ is subject to the material of the circuit board 12′ during working, heat cannot be quickly dissipated from the laser emitter 11′, and temperature of the laser emitter 11′ gets increasingly high as time lasts longer, so that output power of the laser emitter 11′ decreases rapidly as the temperature rises, thereby affecting luminous performance of the laser emitter 11′.

Therefore, how to effectively transmit the heat of the laser emitter 11′ to ensure normal luminous performance of the laser emitter 11′ has become a problem that urgently needs to be resolved.

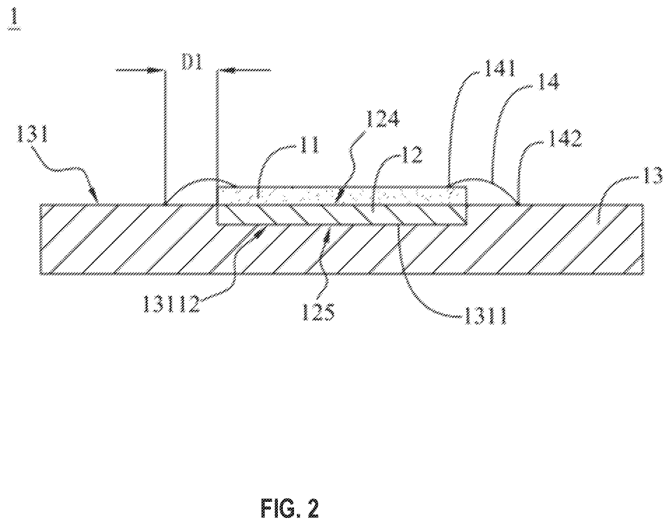

In order to resolve the foregoing technical problem, referring to FIG. 2, a first aspect of this application provides a laser emission module 1, which can effectively transmit heat generated by a laser emitter 11 during working to ensure normal luminous performance of the laser emitter 11.

The laser emission module 1 includes a laser emitter 11, a heat conduction substrate 12 and a first support board 13. The laser emitter 11 has a light emission region, and the heat conduction substrate 12 includes a first board surface 123, where the first board surface 123 is configured to connect the laser emitter 11, and the first board surface 123 covers a region occupied by orthographic projection of the light emission region along a direction perpendicular to the first board surface 123; and the first support board 13 includes a third board surface 131 facing toward the laser emitter 11, where the third board surface 131 is provided with a mounting region 1311, and the heat conduction substrate 12 corresponding to the mounting region 1311 is mounted on the first support board 13.

In some embodiments, the first support board 13 is a circuit support board for supporting a drive circuit for driving the laser emitter 11 to emit light.

In some embodiments, the laser emitter 11 is used as a light source component for emitting light in the laser emission module 1, including at least one laser diode, and each laser diode can be arranged in an array, so that an outgoing laser beam emitted by the laser emission module 1 is at a specific outgoing angle range. In this application condition, the laser emission emitter 11 may have the same type of laser diode arrays, or the laser emission emitter 11 may have different types of laser diode arrays; the laser emitter 11 may use a continuous light source or a pulsed light source; and the laser diode array in the laser emitter 11 may include an LED (light emitting diode), an LD (laser diode), a VCSEL (vertical cavity surface emitting laser device), or the like. This is not limited to these embodiments. Correspondingly, the laser diode arrays in the laser emitter 11 may have the same outgoing power, or the laser diode arrays in the laser emitter 11 may have different outgoing power, which can be designed based on actual application needs.

In some embodiments, the laser emitter 11 has a light emission region, and the “light emission region” can be understood as a region on the laser emitter 11 from which the foregoing a plurality of laser beam signals can be emitted, for example, a region covered by each laser diode in the laser diode array. Herein, a large amount of heat is generated when the laser emitter 11 works to emit light.

The heat conduction substrate 12 is used as a component in the laser emission module 1 that is configured to transmit the heat generated by the laser emitter 11 during working. A specific shape of the heat conduction substrate 12 is not limited herein, and a designer may properly design the shape of the heat conduction substrate 12 based on actual needs. For example, the heat conduction substrate 12 may be rectangular.

The heat conduction substrate 12 is a heat conduction substrate, and the “heat conduction substrate” can be understood as a plate with a good thermal conductivity coefficient. Herein, a specific preparation material of the heat conduction substrate is not limited, and the designer can properly select the preparation material of the heat conduction substrate based on actual needs. For example, the heat conduction substrate can be one of a ceramic substrate, an aluminum substrate, and a Rogers board (The Rogers board is a high-frequency board produced by Rogers, is different from a conventional PCB board—epoxy resin, has no glass fiber in the middle, and uses the ceramic substrate as a high-frequency material. The Rogers board has superior dielectric constants and temperature stability).

In some embodiments, the heat conduction substrate 12 is the ceramic substrate.

In some embodiments, the laser emission module 1 is connected to the laser emitter 11 via a heat conduction substrate 12. That is, the heat generated by the laser emitter 11 during working is transmitted between the heat conduction substrate 12 and the laser emitter 11 via heat conduction (the heat is transmitted via contact between objects at different temperature).

The heat conduction substrate 12 covers at least part of the region occupied by the orthographic projection of the light emission region along the direction perpendicular to the first board surface 123 of the heat conduction substrate 12. That is, at least some laser diodes located in the light emission region are covered by the heat conduction substrate 12 and are within a heat conduction range of the heat conduction substrate 12, so that heat can be dissipated by the heat conduction substrate 12. In some embodiments, the laser diodes located in the light emission region are all covered by the heat conduction substrate 12 and are all within the heat conduction range of the heat conduction substrate 12, so that the heat conduction substrate 12 dissipates heat from all the laser diodes in the laser emitter 11 and a heat conduction effect of the heat conduction substrate 12 is optimized. Herein, the first board surface 123 is on a side of the heat conduction substrate 12 that faces toward the laser emitter 11.

The first support board 13 is used as a component for supporting the drive circuit in the laser emission module 1. A specific shape of the first support board 13 is not limited herein, and a designer may properly design the shape of the first support board 13 based on actual needs. For example, the first support board 13 may be rectangular. Similarly, herein, a specific preparation material of the first support board 13 is not limited, and the designer can select a material with a good thermal conductivity coefficient based on actual needs.

In some embodiments, the first support board 13 has a third board surface 131, and the third board surface is on a side of the first support board 13 that faces toward the laser emitter 11.

The third board surface 131 may be provided with a drive circuit, the drive circuit may be distributed on the third board surface 131 in a form of a printed circuit, and the printed circuit may be formed on the third board surface 131 of the first support board 13 through a yellow light process (exposure, development, and etching).

The third board surface 131 also has a mounting region 1311, and the heat conduction substrate 12 corresponding to the mounting region 1311 is disposed on the first support board 13. That is, the “mounting region 1311” is a region that is formed on the third board surface 131 and on which the heat conduction substrate 12 is mounted. The mounting region 1311 can be a solid structure or a virtual structure, and a specific manifestation of the mounting region 1311 is introduced below.

Based on the laser emission module 1 in the embodiments of this application, the heat conduction substrate 12 is designed to be connected to the laser emitter 11, and therefore, the heat generated by the laser emitter 11 during working can be quickly transmitted to the heat conduction substrate 12, and then the heat conduction substrate 12 quickly transmits the heat to the first support board 13 or a heat dissipation structure 21, so that the heat is not accumulated on the laser emitter 11, thereby ensuring performance and efficiency of the laser emitter 11 during working for long time. In addition, the heat conduction substrate 12 is disposed corresponding to the mounting region 1311 of the first support board 13, and only a heat conduction substrate 12 having a size close to that of the laser emitter 11 is required to achieve a good heat dissipation effect on the laser emitter 11 without a need to use the heat conduction substrate to produce the entire first support board 13 to dissipate heat from the laser emitter 11, which can reduce a size of the required heat conduction substrate, thereby reducing an overall volume and production costs of the laser emission module.

In consideration that the heat conduction substrate 12 not only can be configured to transmit the heat generated by the laser emitter 11 during working, but also can be configured to support the laser emitter 11, and the first support board 13 not only provides a drive electrical signal for the laser emitter 11 via the drive circuit, but also can be configured to support the heat conduction substrate 12 and transmit the heat transmitted by the laser emitter 11 to the heat conduction substrate 12. In order to ensure that the heat conduction substrate 12 has both a good heat conduction effect and a good support effect on the laser emitter 11, an electrical connection relationship between the first support board 13 and the laser emitter 11 is stable, and the first support board 13 has both a good heat conduction effect and a good support effect on the heat conduction substrate 12, design requirements for sizes of the heat conduction substrate 12 and the laser emitter 11 and a relative positional relationship between the heat conduction substrate 12 and the first support board 13 can be but not limited to one or more of the following embodiments.

As shown in FIG. 2, in some embodiments, along a direction parallel to the first board surface 123 of the heat conduction substrate 12, the size of the heat conduction substrate 12 is equal to the size of the laser emitter 11. That is, along the direction perpendicular to the first board surface 123 of the heat conduction substrate 12, the laser emitter 11 forms a first orthographic projection region on the first board surface 123 of the heat conduction substrate 12, and the first orthographic projection region is completely overlapped with the first board surface 123 of the heat conduction substrate 12. With such design, not only it can be ensured that the heat conduction substrate 12 has a good heat conduction effect on the laser emitter 11, but also it can be ensured that the heat conduction substrate 12 has a good support effect on the laser emitter 11, thereby enhancing structural stability of the laser emitter 11 and the heat conduction substrate 12.

In some embodiments, along a direction parallel to the first board surface 123 of the heat conduction substrate 12, a size of the heat conduction substrate 12 is unequal to a size of the laser emitter 11, and an absolute value of a difference between the size of the heat conduction substrate 12 and the size of the laser emitter 11 is within a first preset range (D1 shown in FIG. 2). That is, along the direction perpendicular to the first board surface 123 of the heat conduction substrate 12, the laser emitter 11 forms a second orthographic projection region on the first board surface 123 of the heat conduction substrate 12, and the second orthographic projection region is within a defined region range on the first board surface 123 of the heat conduction substrate 12, or the second orthographic projection region is outside the defined region range on the first board surface 123 of the heat conduction substrate 12. It can be understood that the size of the laser emitter 11 depends on a specific model thereof, and the laser emitter 11 and the drive circuit on the third board surface 131 of the first support board 13 need to be electrically connected through a wire 14 (that is, bonding), and the wire 14 has a first end 141 connected to the laser emitter 11 and a second end 142 connected to the drive circuit. In order to avoid interference to the wire 14 caused by an excessive size of the heat conduction substrate 12 and interference to an electrical connection between the laser emitter 11 and the drive circuit arranged on the third board surface 131, along the direction parallel to the first board surface 123 of the heat conduction substrate 12, a distance between the second end 142 of the wire 14 and an outer peripheral side surface of the laser emitter 11 is defined as a first safety distance, and a “first preset range” can be understood as a value interval that does not exceed the preceding first safety distance. Herein, the first safety distance depends on an actual bonding requirement for the laser emitter 11 and a bonding effect that can be achieved by a bonding device. It should be noted that the smaller the value of the first preset range, that is, the closer the size of the heat conduction substrate 12 along the direction of the first board surface 123 is to the size of the laser emitter 11, the easier the bonding of the laser emitter 11 and the printed circuit on the third board surface 131 of the heat conduction substrate 12 via the wire 14. With such design, not only it can be ensured that the heat conduction substrate 12 has a good heat conduction effect on the laser emitter 11, but also it can be ensured that an electrical connection relationship between the first support board 13 and the laser emitter 11 is stable and the heat conduction substrate 12 can further have a good support effect on the laser emitter 11, thereby enhancing structural stability of the laser emitter 11 and the heat conduction substrate 12.

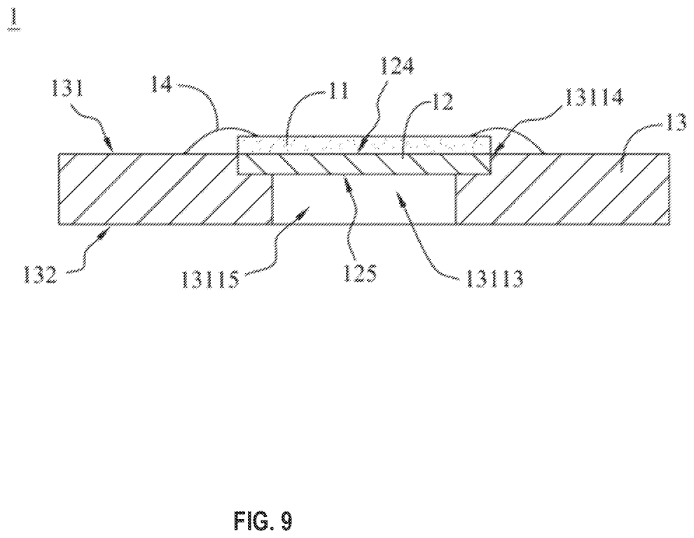

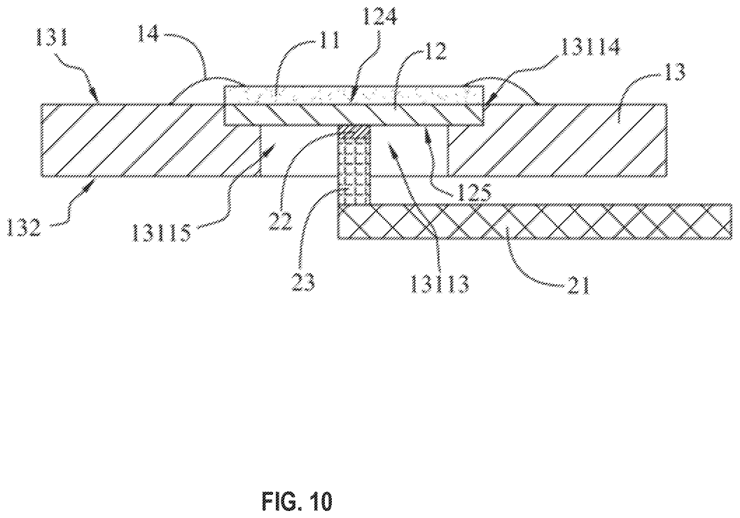

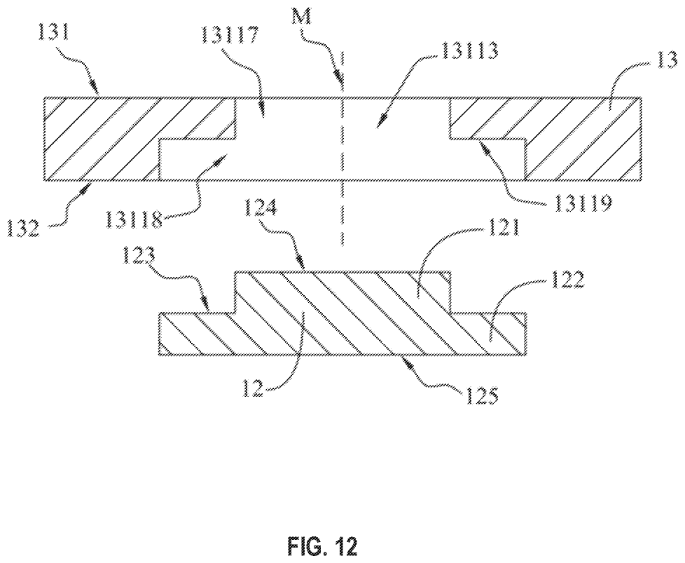

As shown in FIG. 2, FIG. 9, FIG. 10, and FIG. 12, in some embodiments, along a direction perpendicular to the first board surface 123 of the heat conduction substrate 12, the first board surface 123 of the heat conduction substrate 12 that is configured to connect the laser emitter 11 is flush with the third board surface 131 of the first support board 13 that faces toward the laser emitter 11. In other words, the first board surface 123 of the heat conduction substrate 12 that is configured to connect the laser emitter 11 and the third board surface 131 of the first support board 13 that faces toward the laser emitter 11 are located in the same plane. With such design, not only it can be ensured that an electrical connection relationship between the first support board 13 and the laser emitter 11 is stable, but also it can be ensured that the first support board 13 has a good heat conduction effect on the heat conduction substrate 12, and the first support board 13 can further have a good support effect on the heat conduction substrate 12, thereby enhancing structural stability of the heat conduction substrate 12 and the first support board 13.

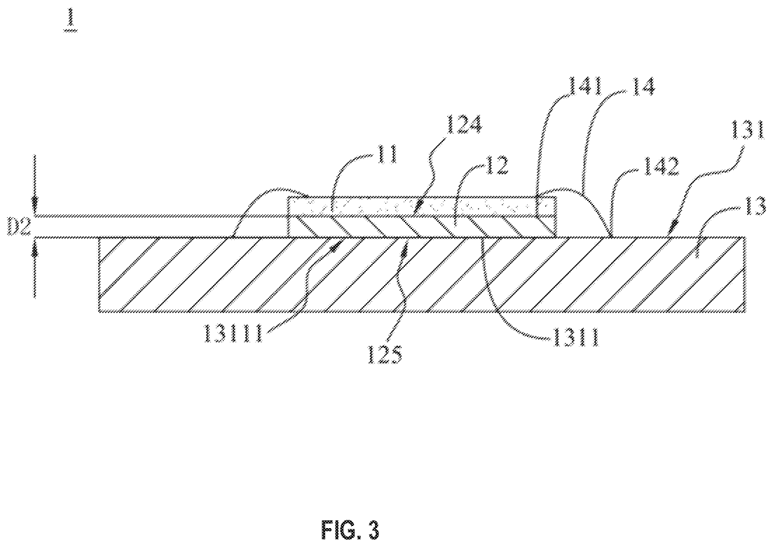

As shown in FIG. 3 and FIG. 12, in some embodiments, the first board surface 123 of the heat conduction substrate 12 that is configured to connect the laser emitter 11 and the third board surface 131 of the first support board 13 that faces toward the laser emitter 11 are spaced apart, and a distance between the first board surface 123 and the third board surface 131 is within a second preset range (D2 shown in FIG. 3). That is, an end of the heat conduction substrate 12 that is closer to the laser emitter 11 can be completely or partially embedded in the first support board 13, or the entire heat conduction substrate 12 can be on a side of the first support board 13 that is closer to the laser emitter 11. In other words, the first board surface 123 of the heat conduction substrate 12 that is configured to connect the laser emitter 11 and the third board surface 131 of the first support board 13 that faces toward the laser emitter 11 are not in the same plane, and the first board surface 123 of the heat conduction substrate 12 that is configured to support the laser emitter 11 may be closer to the laser emitter 1I than the third board surface 131 of the first support board 13 that faces toward the laser emitter 11. Herein, in order to avoid interference to the wire 14 caused because the first board surface 123 of the heat conduction substrate 12 that is configured to connect the laser emitter 11 is excessively higher than the third board surface 131 of the first support board 13 that faces toward the laser emitter 11 and avoid interference to an electrical connection between the laser emitter 11 and the drive circuit arranged on the third board surface 131, along the direction perpendicular to the first board surface 123 of the heat conduction substrate 12, based on an actual bonding requirement, the maximum bonding distance between the first end 141 of the wire 14 and the third board surface 131 is defined as the second safety distance, and a “second preset range” can be understood as a value interval that does not exceed the preceding second safety distance. Herein, the second safety distance depends on an actual bonding requirement for the laser emitter 11 and a bonding effect that can be achieved by a bonding device. It should be noted that the smaller the value of the second preset range, that is, the closer the height of the heat conduction substrate 12 along the direction perpendicular to the first board surface 123 is to the height of the third board surface 131 of the first support board 13 that faces toward the laser emitter 11, the easier the bonding of the laser emitter 11 and the printed circuit on the third board surface 131 of the heat conduction substrate 12 via the wire 14. With such design, not only it can be ensured that an electrical connection relationship between the first support board 13 and the laser emitter 11 is stable, but also it can be ensured that the first support board 13 has both a good heat conduction effect and a good support effect on the heat conduction substrate 12, thereby enhancing structural stability of the heat conduction substrate 12 and the first support board 13.

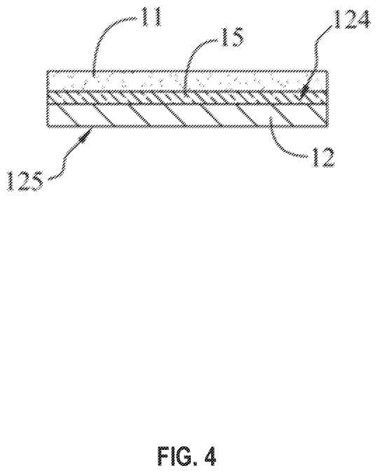

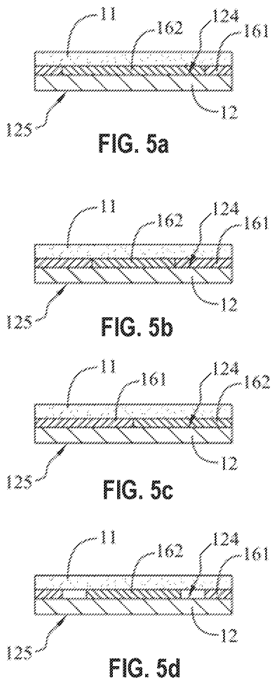

As shown in FIG. 4 and FIGS. 5a-5d, in consideration that the heat conduction substrate 12 is configured to support the laser emitter 11, in order to ensure the connection stability of the heat conduction substrate 12 and the laser emitter 11 and ensure that the heat generated by the laser emitter 11 during working can be effectively transmitted to the heat conduction substrate 12, some intermediate connection structures are needed to implement a structural connection between the heat conduction substrate 12 and the laser emitter 11. A specific connection method of the heat conduction substrate 12 and the laser emitter 11 can be but not limited to the following several embodiments.

As shown in FIG. 4, in some embodiments, the laser emission module 1 further includes a first heat conduction member 15. The first heat conduction member 15 is viscous, the first heat conduction member 15 is filled between the laser emitter 11 and the first board surface 123 of the heat conduction substrate 12, and the first heat conduction member 15 is configured to connect the laser emitter 11 to the heat conduction substrate 12, and further configured to transmit heat of the laser emitter 11 to the heat conduction substrate 12. That is, the first heat conduction member 15 not only can be structurally configured to implement the connection between the laser emitter 11 and the heat conduction substrate 12, but also can be functionally configured to transmit the heat generated by the laser emitter 11 during working to the heat conduction substrate 12. In some embodiments, the first heat conduction member 15 includes a silver paste layer filled between the laser emitter 11 and the heat conduction substrate 12. Herein, the silver paste has good viscosity and the thermal conductivity coefficient, and the silver paste has good heat stability after being baked and cured, which can effectively prevent the first heat conduction member 15 from being deformed when the laser emitter 11 generates heat during working, causing the laser emitter 11 to be displaced, and further affecting the detection performance of the laser emission module 1. The silver paste layer is designed, and as a result, the laser emitter 11 completely fits the heat conduction substrate 12 via the silver paste layer, so that the heat generated by the laser emitter 11 during working can be quickly transmitted to the heat conduction substrate 12. The first heat conduction member 15 may also include a heat conduction glue, and the laser emitter 11 completely fits the heat conduction substrate 12 via the heat conduction glue, so that the heat generated by the laser emitter 11 during working can be quickly transmitted to the heat conduction substrate 12.

As shown in FIG. 5a, in some embodiments, the laser emission module 1 further includes a first binding member 161 and a second heat conduction member 162, the first binding member 161 is viscous, the first binding member 161 is disposed around an edge of the laser emitter 11, to connect the laser emitter 11 to the heat conduction substrate 12; and the second heat conduction member 162 is filled between the laser emitter 11 and the heat conduction substrate 12, and the second heat conduction member 162 is at least partially located in space surrounded by the first binding member 161, to transmit the heat of the laser emitter 11 to the heat conduction substrate 12. That is, the first binding member 161 is solely structurally configured to connect the laser emitter 11 to the heat conduction substrate 12, the second heat conduction member 162 is solely functionally configured to transmit the heat generated by the laser emitter 11 during working to the heat conduction substrate 12, and heat is transmitted among the second heat conduction member 162, the laser emitter 11 and the heat conduction substrate 12 via heat conduction. Both the first binding member 161 and the second heat conduction member 162 are located between the laser emitter 11 and the heat conduction substrate 12, the first binding member 161 is disposed on a periphery of the second heat conduction member 162, and the second heat conduction member 162 may only partially or completely fill the space surrounded by the first binding member 161. Herein, the first binding member 161 may include but not limited to the glue, and the second heat conduction member 162 may include but not limited to a heat conduction material such as heat conduction silicone grease. With such design, the edge of the laser emitter 11 is fixedly connected to the heat conduction substrate 12 via the first binding member 161, and the middle of the laser emitter 11 comes into contact with the heat conduction substrate 12 via the second heat conduction member 162 to transmit heat.

As shown in FIGS. 5b-5d, a relative positional relationship between the first binding member 161 and the second heat conduction member 162 is not limited to a relationship that the first binding member 161 is disposed around the periphery of the second heat conduction member 162, as long as a design of the relative position between the first binding member 161 and the second heat conduction member 162 can ensure good connection stability of the laser emitter 1I and the heat conduction substrate 12 structurally, and also ensure the good thermal conductivity coefficients of the laser emitter 11 and the heat conduction substrate 12 functionally. For example, the second heat conduction member 162 may also be disposed around the periphery of the first binding member 161, or the first binding member 161 and the second heat conduction member 162 may be disposed side by side.

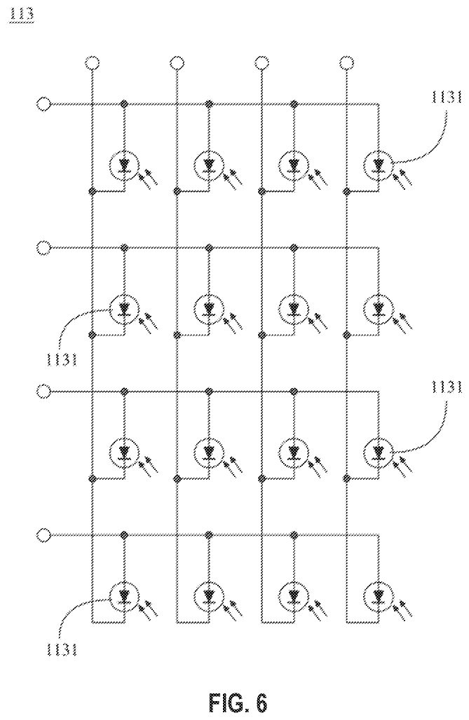

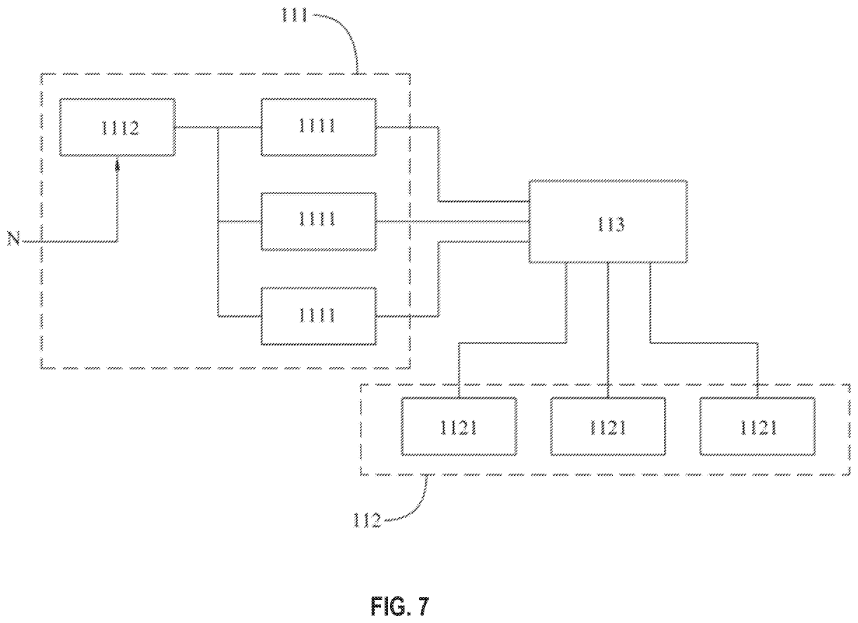

As shown in FIG. 6 and FIG. 7, in consideration that the laser diodes in the laser emitter 11 are arranged into an array to emit a plurality of laser beam signals to a target measured object, the laser emitter 11 may include the laser device array formed by a plurality of laser diodes 1131, and the drive circuit arranged on the third board surface 131 includes an addressable drive circuit. An electrical connection manner of the addressable drive circuit and the laser device array may be but not limited to one or more of the following embodiments.

In some embodiments, the laser device array is a one-dimensional laser device array; and the addressable drive circuit is electrically connected to a plurality of shared positive electrode ends of the one-dimensional laser device array, to perform positive electrode addressing driving on a plurality of rows of laser diodes connected to a plurality of shared positive electrode ends. Herein, positive electrodes of each row of laser diodes are connected to the shared positive electrode ends to form a one-to-one correspondence. In some embodiments, the addressable drive circuit is electrically connected to a plurality of shared negative electrode ends of the one-dimensional laser device array, to perform negative electrode addressing driving on a plurality of columns of laser diodes connected to a plurality of shared negative electrode ends. Herein, negative electrodes of each column of laser diodes are connected to the shared negative electrode ends to form a one-to-one correspondence.

In some embodiments, the laser device array is a two-dimensional laser device array 113, a plurality of laser diodes 1131 are arranged in a two-dimensional array, and the addressable drive circuit includes an positive electrode addressable drive circuit 111 and a negative electrode addressable drive circuit 112; and the positive electrode addressable drive circuit is electrically connected to a plurality of shared positive electrode ends of the two-dimensional laser device array 113, to perform positive electrode addressing driving on a plurality of rows of laser diodes 1131 connected to a plurality of shared positive electrode ends. Herein, positive electrodes of each row of laser diodes are connected to the shared positive electrode ends to form a one-to-one correspondence. The negative electrode addressable drive circuit is electrically connected to a plurality of shared negative electrode ends of the two-dimensional laser device array 113, to perform negative electrode addressing driving on a plurality of columns of laser diodes 1131 connected to a plurality of shared negative electrode ends. Herein, negative electrodes of each column of laser diodes are connected to the shared negative electrode ends to form a one-to-one correspondence.

In some embodiments, the positive electrode addressable drive circuit 111 includes a plurality of positive electrode addressing drive circuits 1111, and the plurality of positive electrode addressing drive circuits 1111 are respectively connected to a plurality of shared positive electrode ends of the laser device array, to perform positive electrode addressing driving on the plurality of rows of laser diodes 1131 connected to the plurality of shared positive electrode ends. The negative electrode addressable circuit 112 includes a plurality of negative electrode addressing drive circuits 1121, and the plurality of negative electrode addressing drive circuits 1121 are respectively connected to a plurality of shared negative electrode ends of the laser device array, to perform negative electrode addressing driving on the plurality of columns of laser diodes 1131 connected to multiple shared negative electrode ends.

For example, as shown in FIG. 7, in some application scenarios, positive electrodes of lasers in the same row in the two-dimensional laser device array 113 are electrically connected and extended to form a shared positive electrode end, and negative electrodes of lasers in the same column in the two-dimensional laser device array 113 are electrically connected and extended to form a shared negative electrode end. The addressable drive circuit of the laser device array includes a positive electrode addressable drive circuit 111 and a negative electrode addressable drive circuit 112. The positive electrode addressable drive circuit 111 includes a plurality of positive electrode addressing drive circuits 1111, and the plurality of positive electrode addressing drive circuits 1111 are respectively connected to multiple shared positive electrode ends corresponding to the multi-row laser device array to form a one-to-one correspondence, and the plurality of positive electrode addressing drive circuits 1111 scan to perform positive electrode addressing driving on the positive electrodes of the plurality of rows of laser devices by externally receiving the positive electrode addressing signal. The positive electrode addressable drive circuit 111 may also include another circuit 1112, another circuit 1112 is connected to a plurality of positive electrode addressing drive circuits 1111, and another circuit 1112 is configured to receive a control signal N. It can be understood that for a different specific application scenario, a specific circuit structure of another circuit 1112 is not always the same. For example, for a specific charging application scenario, another circuit 1112 may be a charging circuit with adjustable energy storage. The negative electrode addressable drive circuit 112 includes a plurality of negative electrode addressing drive circuits 1121, and the plurality of negative electrode addressing drive circuits 1121 are connected to the plurality of shared negative electrode ends corresponding to the multi-column laser device array to form a one-to-one correspondence, and the plurality of negative electrode addressing drive circuits 1121 scan to perform negative electrode addressing driving on the negative electrodes of the plurality of columns of laser devices in the laser device array by externally receiving the negative electrode addressing signal.

In consideration that the heat conduction substrate 12 is disposed corresponding to the mounting region 1311 of the third board surface 131 of the first support board 13. That is, the mounting region 1311 is a region for mounting the heat conduction substrate 12 on the third board surface 131 of the first support board 13. A specific manifestation of the mounting region 1311 may be but not limited to the following embodiments.

As shown in FIG. 3, in some embodiments, the mounting region 1311 is a mounting surface 13111 disposed on the third board surface 131, and the heat conduction substrate 12 also includes a second board surface 124 relative to the first board surface 123; and the second board surface 124 of the heat conduction substrate 12 is attached to the mounting surface 13111. The laser emitter 11 can completely fit the heat conduction substrate 12 via the first heat conduction member 15 (for example, the silver paste layer in FIG. 4) to form a component. Then, the corresponding mounting surface 13111 of the component is attached to the first support board 13, the heat generated by the laser emitter 11 during working can be quickly transmitted to the heat conduction substrate 12, and the heat conduction substrate 12 then quickly transmits the heat to the first support board 13, and the first support board 13 dissipates the collected heat, so that the heat is not accumulated on the laser emitter 11, thereby ensuring performance and efficiency of the laser emitter 11 during working for long time.

As shown in FIG. 2, in some embodiments, the first support board 13 further includes a fourth board surface 132 relative to the third board surface 131. The mounting region 1311 is concavely provided with a recess 13112 in a direction facing toward the fourth board surface 132, the recess 13112 is a blind recess, the second board surface 124 of the heat conduction substrate 12 is attached to a bottom plane of the recess 13112, and at least part of the heat conduction substrate 12 is embedded in the recess 13112. Herein, the heat conduction substrate 12 can be partially or completely embedded in the recess 13112, and when the heat conduction substrate 12 is completely embedded in the recess 13112, the laser emitter 11 can be completely located outside the recess 13112, or can be partially or completely embedded in the recess 13112 provided that a light emission path of the laser emitter 11 is not interfered with. The laser emitter 11 can completely fit the heat conduction substrate 12 via the first heat conduction member 15 (for example, the silver paste layer in FIG. 4) to form a component. Then the recess 13112 corresponding to the component is lowered into the first support board 13, the heat generated by the laser emitter 11 during working can be quickly transmitted to the heat conduction substrate 12, the heat conduction substrate 12 then quickly transmits the heat to the first support board 13, and the first support board 13 dissipates the collected heat, so that the heat is not accumulated on the laser emitter 11, thereby ensuring performance and efficiency of the laser emitter 11 during working for long time.

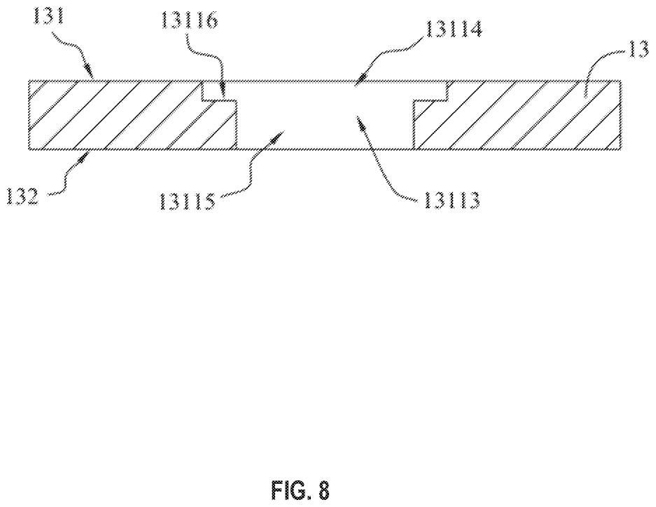

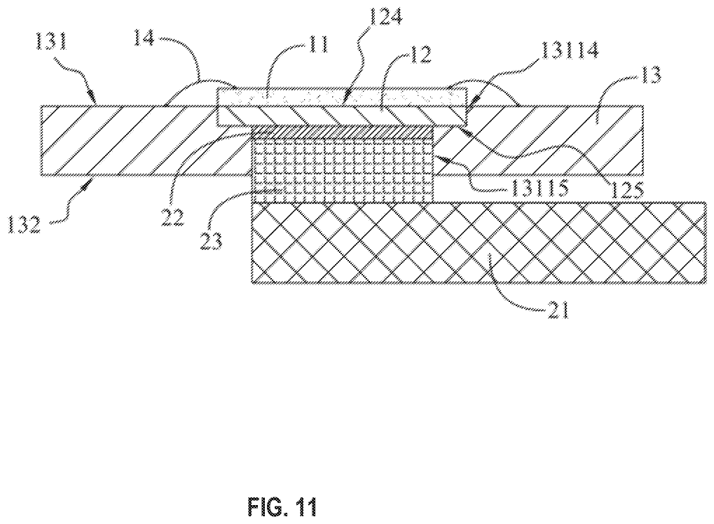

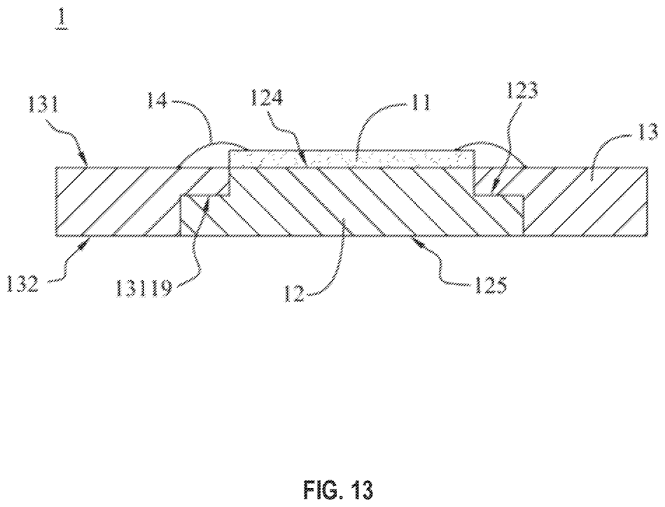

As shown in FIG. 8 and FIG. 10, in some embodiments, the mounting region 1311 has a through hole 13113 penetrating through the third board surface 131 and the fourth board surface 132, and the heat conduction substrate 12 is at least partially embedded in the through hole 13113. In addition, the second board surface 124 of the heat conduction substrate 12 can be located inside the through hole 13113 (FIG. 9, FIG. 10, and FIG. 11), can be flush with the fourth board surface 132 of the first support board 13 (FIG. 13), or can be located outside the through hole 13113 (not shown in the figure).

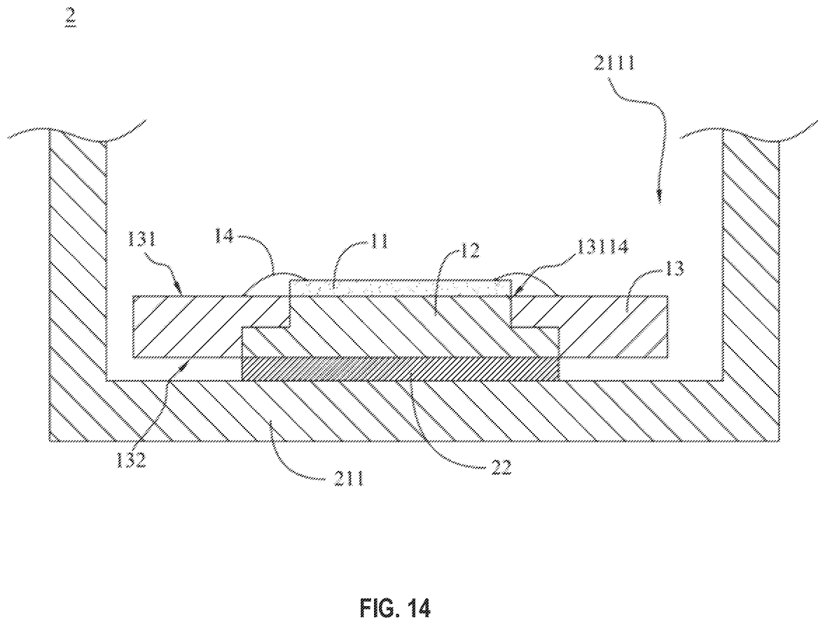

Further, the second board surface 124 of the heat conduction substrate 12 comes into contact with the heat dissipation structure 21 via the first heat conduction element 22, the first heat conduction element 22 is configured to transmit the heat of the heat conduction substrate 12 to the heat dissipation structure 21, and the heat dissipation structure 21 is used for heat dissipation. Herein, in some embodiments, the second board surface 124 of the heat conduction substrate 12 is flush with the fourth board surface 132 of the first support board 13 (shown in FIG. 11 and FIG. 12), and there may be a plane structure (not shown in the figure, where the plane structure may be the inner wall surface of the housing 211) attached to the second board surface 124 on a side of the heat dissipation structure 21 that faces the second board surface 124 of the heat conduction substrate 12. The plane structure comes into contact with the second board surface 124 via the first heat conduction element to absorb the heat on the heat conduction substrate 12 via the first heat conduction element, to further dissipate heat from the heat conduction substrate 12. As shown in FIG. 9 and FIG. 14, in some embodiments, the second board surface 124 is located inside the through hole 13113, and there is a convex structure on the side of the heat dissipation structure 21 that faces the second board surface 124 of the heat conduction substrate 12. The convex structure extends into the through hole 13113, and comes into contact with the second board surface 124 of the heat conduction substrate 12 via the first heat conduction element 22, to absorb the heat on the heat conduction substrate 12 via the first heat conduction element and further dissipate heat from the heat conduction substrate 12. In some embodiments, the second board surface 124 of the heat conduction substrate 12 is located outside the through hole 13113, and there is a concave structure (not shown in the figure) on the side of the heat dissipation structure 21 that faces the second board surface 124 of the heat conduction substrate 12. An end of the heat conduction substrate 12 that is closer to the second board surface 124 can extend into the concave structure, and come into contact with the inner wall of the concave structure via the first heat conduction element, to transmit heat to the heat dissipation structure 21 via the first heat conduction element, and then the heat dissipation structure 21 dissipates the heat from the heat conduction substrate 12.

Herein, the heat conduction substrate 12 can be partially or completely embedded in the through hole 13113, and when the heat conduction substrate 12 is completely embedded in the through hole 13113, the laser emitter 11 can be completely located outside the through hole 13113, or can be partially or completely embedded in the through hole 13113 provided that a light emission path of the laser emitter 11 is not interfered with. The “heat dissipation structure 21” is a structural member for dissipating the heat transmitted to the heat conduction substrate 12 in the laser ranging apparatus. In addition, it can be understood that for a laser ranging apparatus with a different product form, a specific manifestation of the heat dissipation structure 21 is not always the same. The specific manifestation of the heat dissipation structure 21 is introduced below. The “first heat conduction element 22” is a component for transmitting the heat on the heat conduction substrate 12 to the heat dissipation structure 21 quickly in the laser ranging apparatus. The first heat conduction element 22 has good thermal conductivity. For example, the first heat conduction element 22 can include but not limited to heat conduction silicone grease (or referred to as a heat conduction paste or heat dissipation paste) or heat conduction silica gel, in some embodiments, the heat conduction silicone grease. The heat conduction silicone grease has good thermal conductivity and can quickly transmit the heat from the heat conduction substrate 12 to the heat dissipation structure 21, the heat conduction silicone grease is in a gel state with very low hardness, and the cured heat conduction silicone grease barely deforms when heated, which can avoid a change in the position of the heat conduction substrate 12 caused by deformation of the first heat conduction element 22 due to thermal stress and further avoid a change in the position of the laser emitter 11. The laser emitter 11 can completely fit the heat conduction substrate 12 via the first heat conduction member 15 (for example, the silver paste layer in FIG. 4) to form a component. Then the through hole 13113 corresponding to the component is lowered into the first support board 13, the heat generated by the laser emitter 11 during working can be quickly transmitted to the heat conduction substrate 12, the heat conduction substrate 12 quickly transmits some heat to a heat dissipation structure 21 via a first heat conduction element 22 (the heat on the heat conduction substrate 12 is transmitted between the heat conduction substrate 12 and the heat dissipation structure 21 via heat conduction), and the heat dissipation structure 21 dissipates the collected heat, and additionally, the heat conduction substrate 12 then quickly transmits remaining heat to the first support board 13, and the first support board 13 dissipates the collected heat, so that the heat is not accumulated on the laser emitter 11, thereby ensuring performance and efficiency of the laser emitter 11 during working for long time. In addition, it should be noted that the heat dissipation structure 21 fits the first support board 13 to dissipate heat from the heat conduction substrate 12, thereby further increasing a heat dissipation rate of the heat conduction substrate 12.

Further, in consideration that the mounting region 1311 has a through hole 13113 penetrating through the third board surface 131 and the fourth board surface 132, in order to further improve the heat dissipation rate of the heat conduction substrate 12, a specific manifestation of the first through hole 13113, a relative positional relationship between the through hole 13113 and the heat conduction substrate 12, a fitting relationship between the through hole 13113 and the heat conduction substrate 12 and so on can be but not limited to the following several embodiments.

As shown in FIG. 8. FIG. 10 and FIG. 11, in some embodiments, the through hole 13113 includes a first sub-hole 13114 penetrating through the third board surface 131 and a second sub-hole 13115 penetrating through the fourth board surface 132, the first sub-hole 13114 communicates with the second sub-hole 13115, a diameter of the first sub-hole 13114 is greater than a diameter of the second sub-hole 13115 to form a stepped structure 13116, and the heat conduction substrate 12 is located in the first sub-hole 13114 and supported on a stepped surface of the stepped structure 13116. A convex structure 23 is provided on a side of the heat dissipation structure 21 that is closer to the first support board 13. The convex structure 23 extends into the second sub-hole 13115, and comes in contact with the second board surface 124 of the heat conduction substrate 12 via the first heat conduction element 22. Herein, the heat conduction substrate 12 may be completely or partially embedded in the first sub-hole 13114. The “convex structure 23” is a structural member for assisting the heat dissipation structure 21 in dissipating the heat transmitted to the heat conduction substrate 12 in the laser ranging apparatus. In addition, it can be understood that for a through hole 13113 in a different shape, a specific manifestation of the convex structure 23 is not always the same. For example, the convex structure 23 may be a bulge or a pillar integrated on the heat dissipation structure 21. Herein, as shown in FIG. 11, in some embodiments, a side of the convex structure 23 that faces the second board surface 124 can completely cover a surface of the second board surface 124 that is exposed in the through hole 13113, that is, the second sub-hole 13115 is completely filled by the convex structure 23. As shown in FIG. 10, in some embodiments, a side of the convex structure 23 that faces the second board surface 124 can partially cover a surface of the second board surface 124 that is exposed in the through hole 13113, that is, the second sub-hole 13115 is partially filled by the convex structure 23. The heat on the heat conduction substrate 12 is transmitted between the heat conduction substrate 12 and the first support board 13 and between the heat conduction substrate 12 and the convex structure 23 via heat conduction. With such design, the heat conduction substrate 12 is located in the first sub-hole 13114 and supported on the stepped surface of the stepped structure 13116, which enhances the connection stability of the heat conduction substrate 12 and the first support board 13. The design of the convex structure 23 facilitates quick transmission of the heat on the heat conduction substrate 12 to the heat dissipation structure 21, and then the heat on the heat conduction substrate 12 is quickly dissipated by the heat dissipation structure 21, to quickly dissipate the heat of the laser emitter 11 during working, so that the heat is not accumulated on the laser emitter 11, thereby ensuring performance and efficiency of the laser emitter 11 during working for long time. In addition, the heat dissipation structure 21 receives the heat on the heat conduction substrate 12 via the convex structure 23, which facilitates a reduction in the size of the heat dissipation structure 21, thereby reducing an overall volume of a laser ranging apparatus. The convex structure 23 extends into the second sub-hole 13115 and comes into contact with the heat conduction substrate 12 via the first heat conduction element 22, the heat of the heat conduction substrate 12 is quickly transmitted to the convex structure 23 via the first heat conduction element 22, and then transmitted to the heat dissipation structure 21 for heat dissipation via the convex structure 23, so that the heat is not accumulated on the laser emitter 11, thereby ensuring performance and efficiency of the laser emitter 11 during working for long time.

As shown in FIG. 12 and FIG. 13, in some embodiments, the through hole 13113 defines a hole axis M. The through hole 13113 includes a first hole segment 13117 penetrating through the third board surface 131 and a second hole segment 13118 penetrating through the fourth board surface 132. The first hole segment 13117 communicates with the second hole segment 13118, and a diameter of the first hole segment 13117 is less than a diameter of the second hole segment 13118 to form a restrictive structure 13119. The heat conduction substrate 12 includes a connection portion 121 and a restrictive portion 122. The connection portion 121 is disposed on the side of the restrictive portion 122 that is closer to the third board surface 131, and an outer peripheral side surface of the connection portion 121 is closer to the hole axis M than an outer peripheral side surface of the restrictive portion 122 to form an abutment structure 125 that fits the restrictive portion 13119. The connection portion 121 fills at least part of the first hole segment 13117, and the restrictive portion 122 fills at least part of the second hole segment 13118. Herein, the first board surface 123 of the heat conduction substrate 12 (that is, the side of the heat conduction substrate 12 that is configured to connect the laser emitter 11) is on a side of the connection portion 121 that is farther away from the restrictive portion 122; the second board surface 124 of the heat conduction substrate 12 (that is, a side of the heat conduction substrate 12 that is configured to connect the heat dissipation structure 21) is on the side of the connection portion 121 that is farther away from the restrictive portion 122; and a side of the heat dissipation structure 21 that faces the second board surface 124 comes into contact with the end (that is, the second board surface 124) of the restrictive portion 122 that is farther away from the connection portion 121 via the first heat conduction element 22 (shown in FIG. 11). Herein, the side of the connection portion 121 that is farther away from the restrictive portion 122 (that is, the first board surface 123) and the third board surface 131 of the first support board 13 can be flush or spaced at intervals. Similarly, the side of the restrictive portion 122 that is farther away from the connection portion 121 (that is, the second board surface 124) and the fourth board surface 132 of the first support board 13 can be flush or spaced at intervals. The heat conduction substrate 12 is designed to match the through hole 13113 in shape, so that the heat conduction substrate 12 fits the first support board 13, to enhance overall structural strength of the laser emission module 1. The heat conduction substrate 12 is designed to have a restrictive structure 13119 that fits the stepped structure 13116 of the through hole 13113, to implement pre-positioning of the heat conduction substrate 12 before being assembled with the first support board 13 from a side of the first support board 13 with the fourth board surface 132, thereby facilitating assembly of the heat conduction substrate 12 with the first support board 13.

As shown in FIG. 9, in some embodiments, the through hole 13113 includes a first sub-hole 13114 penetrating through the third board surface 131 and a second sub-hole 13115 penetrating through the fourth board surface 132. The first sub-hole 13114 communicates with the second sub-hole 13115, a diameter of the first sub-hole 13114 is greater than a diameter of the second sub-hole 13115 to form a stepped structure 13116, and the heat conduction substrate 12 is located in the first sub-hole 13114 and supported on a stepped surface of the stepped structure 13116. At this time, the second sub-hole 13115 of the through hole 13113 forms a heat dissipation window, the heat conduction substrate 12 quickly transmits some heat to the first support board 13 (the heat on the heat conduction substrate 12 is transmitted between the heat conduction substrate 12 and the first support board 13 via heat conduction), the first support board 13 dissipates the collected heat, and additionally, the heat conduction substrate 12 dissipates remaining heat via the heat dissipation window formed by the second sub-hole 13115 (the heat on the heat conduction substrate 12 is transmitted via heat convection between the heat conduction substrate 12 and the heat dissipation window formed by the second sub-hole 13115), so that the heat is not accumulated on the laser emitter 11, thereby ensuring performance and efficiency of the laser emitter 11 during working for long time.

A second aspect of this application provides a LiDAR, where the LiDAR includes the foregoing laser emission module 1, and further includes a housing (not shown in the figure), the housing has an accommodating cavity, and the laser emission module 1 is disposed in the accommodating cavity 2111.

The laser emission module can also include a laser emission lens (not shown in the figure). The laser emission lens can be on a light-outgoing side of the laser emitter 11 of the laser emission module 1, and can perform optical processing such as angle reduction (reduction in a divergence angle) or beam increase (increase in an angle of view) on light emitted by the laser emitter 11, to enhance intensity of light in the emission field of view, increase the emission field of view and improve detection accuracy and a detection range of the LiDAR 2.

In the design, the LiDAR 2 having the foregoing laser emission module 1 can transmit the heat generated by the laser emitter 11 during working in a timely manner and has a good heat dissipation effect, thereby effectively improving detection performance of the LiDAR 2. Compared with a conventional method of adding a heat sink, because the heat sink is not needed to dissipate heat, mounting space does not need to be specially disposed for the heat sink, thereby facilitating a reduction in a volume and costs of the LiDAR apparatus and also meeting a requirement of light weight.

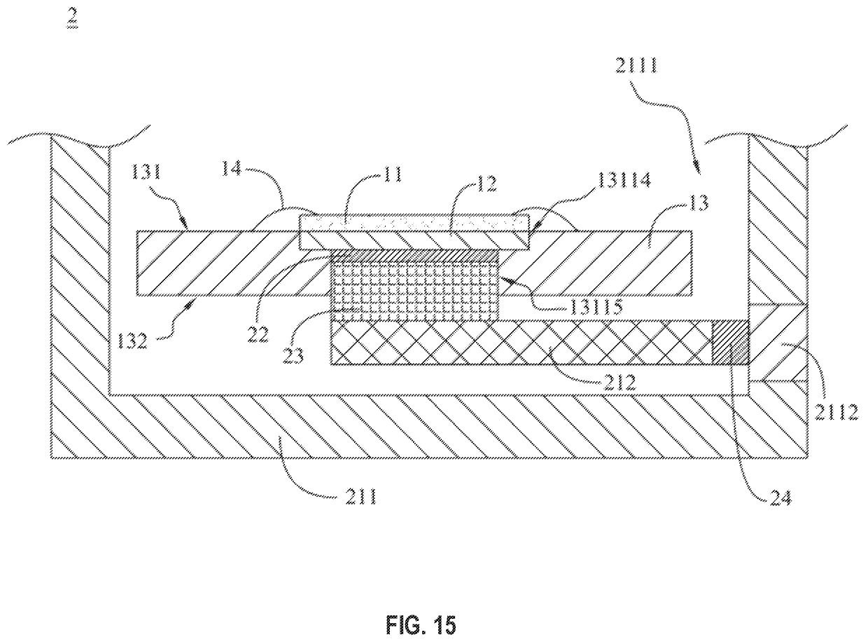

Referring to FIG. 14 and FIG. 15, a third aspect of this application provides LIDAR 2, where the LiDAR 2 includes a laser emission module, and the laser emission module includes the foregoing laser emission module 1 and the foregoing heat dissipation structure 21. Herein, a specific manifestation of the heat dissipation structure 21 can be but not limited to the following embodiments.

As shown in FIG. 14, in some embodiments, the heat dissipation structure 21 includes a housing 211, the housing 211 has an accommodating cavity 2111, the laser emission module 1 is disposed in the accommodating cavity 2111, and the second board surface 124 of the heat conduction substrate 12 comes into contact with a part of an inner wall surface of the housing 211 via the first heat conduction element 22, and transmits heat directly to the housing 211 via the first heat conduction element 22. That is, the heat of the heat conduction substrate 12 is directly transmitted to the housing 211 via the first heat conduction element 22, and then the housing 211 dissipates the heat out of the cavity. Compared with a conventional method of adding a heat sink, because the heat sink is not needed to dissipate heat, mounting space does not need to be specially disposed for the heat sink, thereby facilitating a reduction in volume and costs of the LiDAR apparatus and also meeting a requirement of light weight.

In some embodiments, the inner side wall of the housing 211 that faces the second board surface 124 of the heat conduction substrate 12 has the foregoing plane structure or a convex structure or a concave structure, and the plane structure comes into contact with the second board surface 124 via the first heat conduction element, to absorb the heat on the heat conduction substrate 12 via the first heat conduction element, and further dissipate the heat from the heat conduction substrate 12, thereby dissipating the heat out of the cavity. The convex structure can extend into the through hole 13113 and come into contact with the second board surface 124 of the heat conduction substrate 12 via the first heat conduction element 22, to absorb the heat on the heat conduction substrate 12 via the first heat conduction element, and further dissipate the heat from the heat conduction substrate 12, thereby dissipating the heat out of the cavity. An end of the heat conduction substrate 12 that is closer to the second board surface 124 can extend into the concave structure, and come into contact with an inner wall of the concave structure via the first heat conduction element, to transmit the heat to the housing 211 via the first heat conduction element, so that the housing 211 dissipates the heat from the heat conduction substrate 12, thereby dissipating the heat out of the cavity.

Further, a heat dissipation rib and/or a heat dissipation recess can be provided on the outer wall of the housing 211 corresponding to the second board surface 124. The heat dissipation rib and/or the heat dissipation recess are all configured to dissipate the heat generated by the laser emission module 1 out of the cavity. Specific positions of the heat dissipation rib and/or the heat dissipation recess can be selected based on a specific mounting position of the LiDAR. In some embodiments, there can be a plurality of heat dissipation recesses, the plurality of heat dissipation recesses are arranged at intervals on the outer wall of the housing 211 corresponding to the preset heat dissipation region 2112, and a heat dissipation rib is formed between every two adjacent heat dissipation recesses arranged at intervals. The heat dissipation recess and the heat dissipation rib are disposed on the outer wall of the housing 211, and therefore, not only a heat dissipation area of the outer surface of the housing 211 is increased to improve the heat dissipation rate outside the housing 211 and dissipate the heat generated by the laser emission module 1 out of the cavity via the housing 211 in a timely manner, but also the weight of the housing 211 can be reduced, thereby reducing the weight of the LiDAR.

As shown in FIG. 15, in some embodiments, the heat dissipation structure 21 includes a housing 211 and a heat guiding mechanism 212. The housing 211 has an accommodating cavity 2111, the laser emission module 1 and the heat guiding mechanism 212 are both arranged in the accommodating cavity 2111, and the heat guiding mechanism 212 is between the laser emission module 1 and the inner side wall of the housing 211, and configured to absorb the heat of the laser emission module 1 and transmit the absorbed heat to the housing 211. Herein, an end of the heat guiding mechanism 212 that faces the second board surface 124 of the heat conduction substrate 12 comes into contact with the second board surface 124 via the first heat conduction element 22 to absorb the heat of the heat conduction substrate 12. An end of the heat guiding mechanism 212 that faces the preset heat dissipation region 2112 of the housing 211 comes into contact with the inner wall of the housing corresponding to the preset heat dissipation region 2112 via the second heat conduction element 24, to transmit the absorbed heat to the housing 211 via the second heat conduction element 24, so that the housing 211 dissipates the heat out of the cavity. The second heat conduction element 24 has good thermal conductivity. For example, the second heat conduction element 24 can include but not limited to heat conduction silicone grease (or referred to as a heat conduction paste or heat dissipation paste) or heat conduction silica gel, in some embodiments, the heat conduction silicone grease. The heat conduction silicone grease has good thermal conductivity and can quickly transmit the heat from the heat conduction substrate 12 to the heat dissipation structure 21, the heat conduction silicone grease is in a gel state with very low hardness, and the cured heat conduction silicone grease barely deforms when heated, which can avoid a change in the position of the heat guiding mechanism 212 caused by deformation of the second heat conduction element 24 due to thermal stress and further avoid a change in the position of the laser emitter 11.

In some embodiments, the heat guiding mechanism 212 is configured to change a transmission direction of the absorbed heat to guide the heat to the preset heat dissipation region 2112 of the housing 211. That is, the heat of the heat conduction substrate 12 is transmitted to the heat guiding mechanism 212 via the first heat conduction element 22, and then indirectly transmitted to the housing 211 via the heat guiding mechanism 212 and the second heat conduction element 24. Herein, the “heat guiding mechanism 212” is a structural member in the heat dissipation structure 21 that is configured to absorb the heat on the heat conduction substrate 12 and change the transmission direction of the heat. For example, the heat guiding mechanism 212 may be a guide rod or a guide plate with a good heat conduction effect. The “preset heat dissipation region 2112” is understood as a region on the housing 211 in which the heat concentrated on the heat guiding mechanism 212 can be dissipated, and a heat dissipation rib, a heat dissipation recess and/or heat dissipation teeth can be provided on the outer wall of the housing 211 corresponding to this region. The heat dissipation rib, the heat dissipation recess and/or the heat dissipation teeth are all configured to dissipate the heat generated by the laser emission module 1 out of the cavity. The specific position of the preset heat dissipation region 2112 can be selected based on a specific mounting position of the LiDAR. In some embodiments, there can be a plurality of heat dissipation recesses, the plurality of heat dissipation recesses are arranged at intervals on the outer wall of the housing 211 corresponding to the preset heat dissipation region 2112, and a heat dissipation rib is formed between every two adjacent heat dissipation recesses arranged at intervals. The heat dissipation recess and the heat dissipation rib are disposed on the outer wall of the housing 211 corresponding to the preset heat dissipation region 2112, and therefore, not only a heat dissipation area of the outer surface of the housing 211 is increased to improve the heat dissipation rate outside the housing 211 and dissipate the heat generated by the laser emission module 1 out of the cavity via the housing 211 in a timely manner, but also the weight of the housing 211 can be reduced, thereby reducing the weight of the LiDAR.

In the design, the LiDAR 2 having the foregoing laser emission module 1 and the foregoing heat dissipation structure 21 directly transmits heat to the housing 211 via the first heat conduction element 22, or transmits the heat to the first heat conduction element 22 and then indirectly transmits the heat to the preset heat dissipation region 2112 of the housing 211 via the heat guiding mechanism 212 and the second heat conduction element 24 during working, which can transmit the heat generated by the laser emitter 11 in a timely manner and therefore, achieves a good heat dissipation effect, thereby effectively improving detection performance of the LiDAR 2.

In some embodiments, the number of laser emission modules is two, and the LiDAR 2 also includes a laser beam receiving module (not shown in the figure), the two laser emission modules are respectively on opposite sides of the laser beam receiving module, and a combination of emission fields of view of the two laser emission modules matches a receiving field of view of the laser beam receiving module.

In some embodiments, each laser emission module can also include a laser emission lens (not shown in the figure), and the laser emission lens can be on a light-outgoing side of the laser emitter 11 of the laser emission module 1, and can perform optical processing such as angle reduction (reduction in a divergence angle) or beam increase (increase in an angle of view) on light emitted by the laser emitter 11, to enhance intensity of light in the emission field of view, increase the emission field of view and improve detection accuracy and a detection range of the LiDAR 2.

The laser beam receiving module can include a laser beam receiving lens and a laser beam detector. The laser beam receiving lens can be on a light-incident side of the laser beam detector and is configured to receive a reflected laser beam and focus the reflected laser beam on the laser beam detector.

The foregoing descriptions are only preferred embodiments of this application, and are not intended to limit this application. Any modification, equivalent replacement and improvement made within the spirit and principle of this application shall be included within the protection scope of this application.

In the prior art, the laser diode is packaged to form the laser emission chip for emitting the laser. The laser emission chip is mounted on a PCB (Printed Circuit Board) and electrically connected to the PCB so that the PCB controls the laser emission chip to emit laser detecting signals. The laser emission chip is usually affixed to the PCB. Therefore, the heat generated during the operation of the laser emission chip needs to be discharged from the PCB. However, the commonly used PCB has a low thermal conductivity coefficient. According to the relationship between the thermal conductivity coefficient and heat dissipation effect: the larger the thermal conductivity coefficient, the better the heat dissipation effect: the smaller the thermal conductivity coefficient, the worse the heat dissipation effect. The PCB with the lower thermal conductivity coefficient cannot discharge the heat generated during the operation of the laser emission chip in a timely manner, which leads to the reduction of the working stability of the laser emission chip.

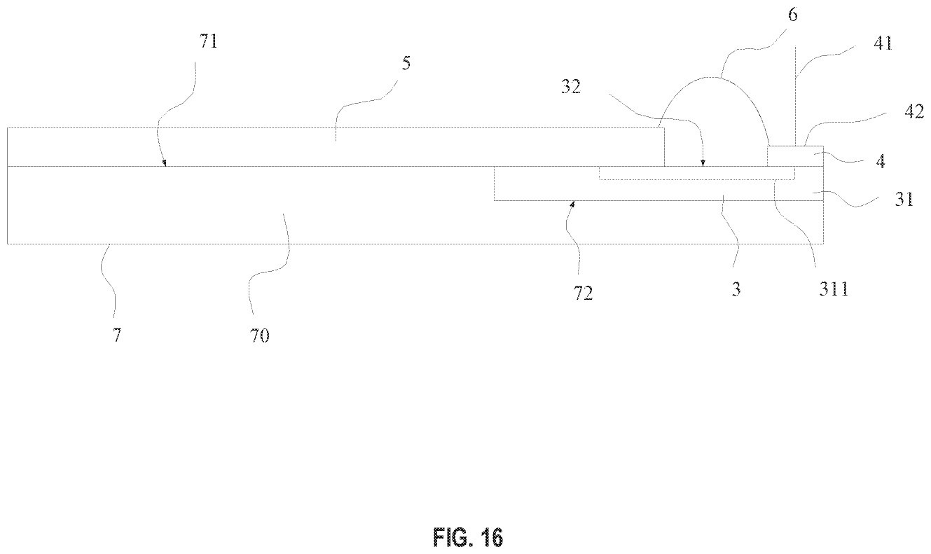

Referring to FIG. 16, to solve the forgoing problems, this application provides a laser emission apparatus, where the laser emission apparatus includes at least a ceramic carrier 3, a laser emission chip 4, and a circuit board 5.

The ceramic carrier 3 can be directly bonded to a carrier made of alumina or aluminum nitride, etc. via copper foil at a high temperature, that is, the copper foil is packaged in alumina or aluminum nitride, etc. Using the electrical conductivity of aluminum foil, the ceramic carrier 3 has electrical conductivity. In additions, alumina or aluminum nitride, etc., has thermal conductivity and the larger thermal conductivity coefficient, so that the ceramic carrier 3 has the higher thermal conductivity, and hence can discharge heat in a timely manner.

Further, the shape of the ceramic carrier 3 can be set according to actual needs. The ceramic carrier 3 can be a board-shaped ceramic substrate. In some embodiments, the ceramic substrate is a process board obtained by the copper foil bonded to the surface (single-surface or double-surface) of an alumina or aluminum nitride ceramic substrate. In some embodiments, the ceramic carrier 3 can also be block-shaped or spherical, and so on.

The laser emission chip 4 is configured to transmit detecting signals (a laser beam) and generate more heat when the laser emission chip 4 is in operation. If the laser emission chip 4 is overheated, the wavelength of the laser beam is excessively drifted, thus resulting in the degradation of the performance of LiDAR. Therefore, by mounting the laser emission chip 4 on the ceramic carrier 3, the heat generated by the laser emission chip 4 can be discharged in a timely manner due to the larger thermal conductivity coefficient of the ceramic carrier 3. The laser emission chip 4 can be affixed to the ceramic carrier 3 to increase the contact area with the ceramic carrier 3, which can further improve the heat dissipation rate of the laser emission chip 4.

In some embodiments, the ceramic carrier 3 can be provided as the board-shaped ceramic substrate. The laser emission chip 4 is affixed to the surface of the ceramic substrate. In some embodiments, the ceramic carrier 3 can be block-shaped or spherical. The ceramic carrier 3 can be opened and provided with a recess. The laser emission chip 4 can be mounted and fixed in the recess, so that the ceramic carrier 3 can be located around the circumference of the laser emission chip 4. The contact area between the laser emission chip 4 and the ceramic carrier 3 can be further increased, which in turn can improve the heat dissipation rate of the laser emission chip 4. Further, the size and shape of the recess need to be set according to the actual size and shape of the ceramic carrier 3.

The circuit board 5 is electrically connected to the laser emission chip 4 and forms a laser emission loop, i.e., the circuit board 5 is configured to control the laser emission chip 4 to emit the laser beam at a target emission power as needed.

Referring to FIG. 16, in some embodiments, to increase the contact area between the laser emission chip 4 and the ceramic carrier 3, the ceramic carrier 3 may be provided with a mounting surface 32. The laser emission chip 4 is mounted and affixed to the mounting surface 32. In additions, the orthographic projection of the laser emission chip 4 on the mounting surface 32 is located within the mounting surface 32, i.e., the laser emission chip 4 is located within the mounting surface 32, so that the contact surface between the laser emission chip 4 and the ceramic carrier 3 is larger.

Considering the higher cost of the ceramic carrier 3 and the smaller heat generated by the circuit board 5, see FIG. 2, the circuit board 5 and the ceramic carrier 3 can arranged at intervals. The laser emission chip 4 is mounted in the ceramic carrier 3, so that the ceramic carrier 3 can be made smaller to save costs. The shape of the ceramic carrier 3 can be set according to the shape and size of the laser emission chip 4 to meet the needs of the laser emission chip 4 for a mounting position.

Taking as an example the ceramic carrier 3 and the PCB are both made of aluminum nitride ceramic, the thermal conductivity coefficient of an aluminum nitride ceramic carrier 3 is 170 W/(m−K), and the thermal conductivity coefficient of PCB is 16.5 W/(m−K). Therefore, the thermal conductivity coefficient of the aluminum nitride ceramic carrier 3 is much larger than that of the PCB. Compared to the prior art where the laser emission chip 4 is mounted on the PCB, the laser emitter chip 4 is mounted on the aluminum nitride ceramic carrier 3, which can increase the heat dissipation rate of the laser emitter chip 4. In some embodiments, the circuit board 5 and the laser emission chip 4 are arranged at the intervals to avoid the contact between the laser emission chip 4 and the circuit board 5, which affects the heat dissipation of the laser emission chip 4, and also prevents the heat generated by the laser emission chip 4 from being conducted to the circuit board 5 to hence cause the circuit board 5 to expand.

In order to achieve the ceramic carrier 3 and circuit board 5 that are arranged at the intervals, in some embodiments, the ceramic carrier 3 can be located on either side of the circuit board 5, for example, the ceramic carrier 3 can be located on the top side, the bottom side, the left side, the right side, the front side or the back side of the circuit board 5. In some embodiments, the position of the ceramic carrier 3 relative to the circuit board 5 can be adjusted according to the actual situation.

In some embodiments, the circuit board 5 can also be partially overlapped with the ceramic carrier 3. In some embodiments, the circuit board 5 is located on the upper or lower sides of the ceramic carrier 3 and in contact with the ceramic carrier 3, that is, a part of the projection of the circuit board 5 along a thickness direction thereof is located in the range of the ceramic carrier 3, so that the circuit board 5 is in contact with the ceramic carrier 3. Due to the larger thermal conductivity coefficient of the ceramic carrier 3, the heat generated by the circuit board 5 can be discharged in a timely manner, so that the circuit board 5 can be operated in a more suitable temperature conditions, which can ensure that the operation speed of the circuit board 5.

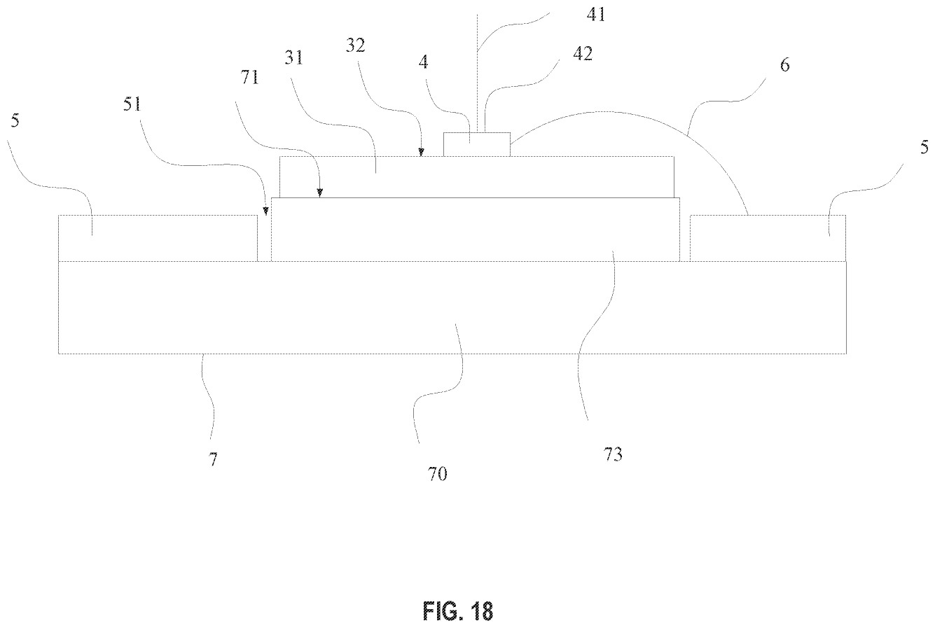

In some embodiments, see FIG. 18, the circuit board 5 can has an avoidance hole 51. The ceramic carrier 3 is at least partly arranged in the avoidance hole 51. The ceramic carrier 3 and the wall of the avoidance hole 51 are arranged at intervals, that is, the ceramic carrier 3 passes through and is provided at the avoidance hole 51. In some embodiments, the ceramic carrier 3 can be block-shaped or cylindrical, etc. Correspondingly, the shape of the avoidance hole 51 can be set to match the ceramic carrier 3, so that the ceramic carrier 3 passes through and is provided in the avoidance hole 51. In additions, the circumference of the ceramic carrier 3 and the wall of the avoidance hole 51 are arranged at intervals, so that when the ceramic carrier 3 has an increase in volume due to thermal expansion, the increased volume can be accommodated in the intervals, thus avoiding extrusion to the circuit board 5.

In some embodiments, to meet the more stringent temperature control needs, the circuit board 5 can also be connected to the ceramic carrier 3, so that the circuit board 5 is in contact with the ceramic carrier 3. The larger thermal conductivity coefficient of the ceramic carrier 3 is utilized to discharge the heat generated by the circuit board 5 in a timely manner, which can reduce the temperature of the laser emission apparatus, and provide the laser emission chip 4 with a temperature-appropriate operating environment, so as to improve the operation stability of the laser emission chip 4.

In some embodiments, the laser emission chip 4 can be bonded (using an adhesive with electrical conductivity, such as a silver paste, etc.), welded, or electrically connected by a wire to the aluminum foil in the ceramic carrier 3, so that the laser emission chip 4 can be connected to the aluminum foil in the ceramic carrier 3 to achieve the transmission of electrical signals. The circuit board 5 can be bonded, welded, or connected by the wire 6 to the aluminum foil in the ceramic carrier 3, so that the circuit board 5 can transmit the electrical signals with the aluminum foil in the ceramic carrier 3. In some embodiments, a suitable connection method can be selected according to actual operation and the position of a mounting space.

In some embodiments, the circuit board 5 can be abutted against and electrically connected to the laser emission chip 4 to form the laser emission loop. In some embodiments, the side of the circuit board 5 near the laser emission chip 4 can be provided with a first pin (not shown in the figures). In additions, the side of the laser emission chip 4 near the circuit board 5, and the position corresponding to the first pin are provided with a second pin. The first pin can be directly abutted against the second pin, so that the first pin is electrically connected to the second pin. A specific connection method can be tin welding, or either of the first pin and the second pin is provided with a snap post thereon, and the other thereof is provided with a snap ring. The snap post cooperates with the snap ring so that the first pin and the second pin are snapped together. The first pin and the second pin can also be electrically welded contact points.

In some embodiments, see FIG. 16, the laser emission apparatus can also include the wire 6. The ceramic carrier 3 is provided therein with the aluminum foil, so that the circuit board 5, the wire 6, the laser emission chip 4, the aluminum foil in the ceramic carrier 3, and the circuit board 5 are electrically connected in sequence to form a laser emission loop. Therefore, the circuit board 5 can control the laser emission chip 4 to emit the detecting signals (the laser beam). It can be understood that the circuit board and the emission chip can be structurally abutted against each other or arranged at the intervals. This application does not limit the relationship between the positions of the circuit board and the emission chip.

In some embodiments, one end of the wire 6 is electrically connected to a first terminal (not shown in the figures) on the circuit board 5, and the other end thereof is electrically connected to a second terminal (not shown in the figures) on the laser emission chip 4. One end of the aluminum foil in the ceramic carrier 3 is electrically connected to a third terminal (not shown in the figures) on the laser emission chip 4, and the other end thereof is electrically connected to a fourth terminal (not shown in the figures) on the circuit board 5. A specific electrical connection method can be the tin welding, bonding with an adhesive with electrical conductivity, or an electrical connection method that can also be known to a person skilled in the art. This application does not limit the connection method specifically.

Based on the above embodiments, when a current is delivered via the aluminum foil, the alumina or aluminum nitride ceramic has the larger thermal conductivity coefficient, so that the heat generated by the aluminum foil when delivering the current can be discharged in a timely manner. Therefore, the aluminum foil has a lower temperature rise rate, thus providing a temperature-appropriate operating environment for the laser emission chip 4 to improve the operating performance of the laser emission chip 4. It should be noted that the wire 6 can be a copper wire, an aluminum wire, or a silver wire, etc., which can be set according to the actual needs of the electrical conductivity.

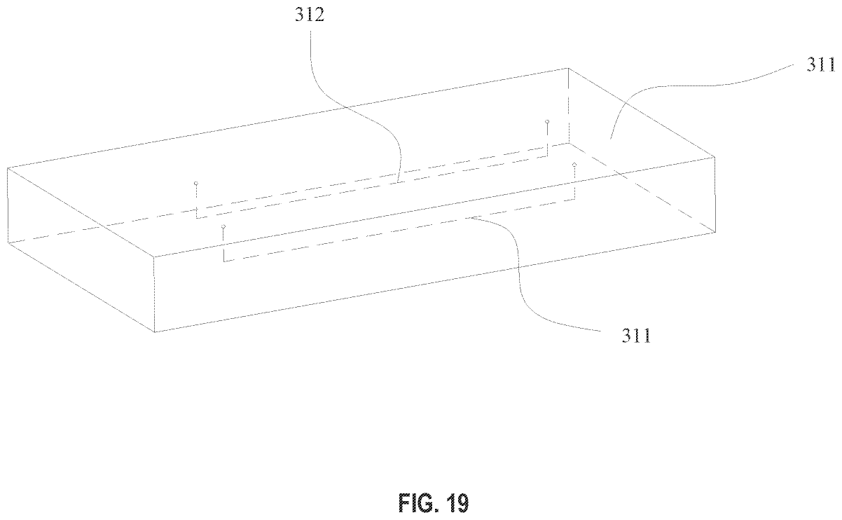

In some embodiments, see FIG. 19, the ceramic carrier 3 includes an insulating substrate 31, as well as a first electrically conductive part 311 and a second electrically conductive part 312 that are arranged in the insulating substrate 31 and mutually insulated. The first electrically conductive part 311 and the second electrically conductive part 312 can be copper, aluminum and silver and other electrically conductive materials, so that the first electrically conductive part 311 and second electrically conductive part 312 have electrical conductivity. Further, the circuit board 5, the first electrically conductive part 311, the laser emission chip 4, the second electrically conductive part 312, and the circuit board 5 are electrically connected in sequence to form a laser emission loop, so that the circuit board 5 can control the laser emission chip 4 to emit the detecting signals (the laser beam).

It should be noted that the first electrically conductive part 311 and the second electrically conductive part 312 are electrically connected to the circuit board 5 and the laser emission chip 4. A specific electrical connection method can be the tin welding, bonding with the adhesive with electrical conductivity, or an electrical connection method that can also be known to a person skilled in the art. This application does not limit the connection method specifically.

The laser emission apparatus may also include a first wire (not shown in the figures) and a second wire (not shown in the figures). The circuit board 5, the first wire, the laser emission chip 4, the second wire, the circuit board 5 are electrically connected in sequence to form a laser emission loop. The first wire and the second wire are electrically connected to the circuit board 5 and the laser emission chip 4, respectively. A specific electrical connection method can be the tin welding, bonding with the adhesive with electrical conductivity, or an electrical connection method that can also be known to a person skilled in the art. This application does not limit the connection method specifically. In some embodiments, to mount and fix the circuit board 5 and ceramic carrier 3, see FIGS. 16 to 18, the laser emission apparatus also includes a heat dissipation support member 7. The ceramic carrier 3 and the circuit board 5 are both arranged on the heat dissipation support member 7. It should be noted that the ceramic carrier 3 and circuit board 5 are both in contact with the heat dissipation support member 7, so that the heat discharged by the ceramic carrier 3 and the circuit board 5 is dissipated through the heat dissipation support member 7. On the other hand, the heat dissipation support member 7 can provide a base for mounting and fixing the ceramic carrier 3 and the circuit board 5.

It should be noted that the heat dissipation support member 7 can be made of metal, such as copper, aluminum, and aluminum alloy, etc. By utilizing the thermal conductivity of the metal, the heat discharged by the ceramic carrier 3 and the circuit board 5 is dissipated through the heat dissipation support member 5. Further, the metal has a certain degree of hardness, and can provide a more solid support for the ceramic carrier 3 and the circuit board 5. In some embodiments, the heat dissipation support member 7 can also be made of graphite with thermal conductivity, etc.

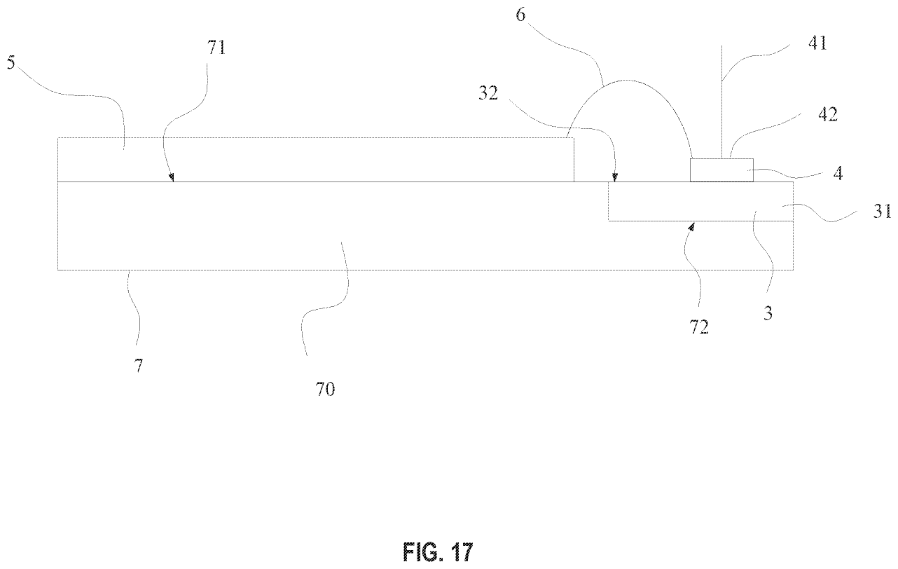

Referring to FIGS. 16 to 17, in some embodiments, the heat dissipation support member 7 includes a metal board 70. The metal board 70 includes a bearing surface 71, the bearing surface 71 is open and provided with a mounting groove 72. The circuit board 5 is at least partially mounted on the bearing surface 71. The ceramic carrier 3 is arranged in the mounting groove 72. The laser emission chip 4 is mounted on the surface of the ceramic carrier 3 away from the bottom of the mounting groove 72. It should be noted that the metal board 70 can be made of iron, aluminum, and copper-aluminum alloy, etc. It should be noted that the shape and size of the mounting groove 72 can be set according to the actual shape and size of the ceramic carrier 3. There is no specific limitation in this application.

In some embodiments, one side of the metal board 70 is the bearing surface 71. The circuit board 5 is located on the bearing surface 71, that is, a part of the circuit board 5 corresponds to the bearing surface 71, so that the circuit board 5 is mounted and fixed on the metal board 70. The circuit board 5 can be bonded, snapped, or screwed on the metal board 70. It should be noted that the adhesive with the thermal conductivity coefficient can be used to bond. On the basis of the circuit board 5 being connected to the metal board 50, the heat generated by the operation of the circuit board 5 can be dissipated through the metal board 70, thus improving the heat dissipation rate of the circuit board 5.

In some embodiments, the ceramic carrier 3 may be board-shaped. The board-shaped ceramic carrier 3 is arranged behind the mounting groove 72. The surface of the ceramic carrier 3 away from the bottom of the mounting groove 72 is flush with the bearing surface 71. A part of the circuit board 5 is pressed against the ceramic carrier 3 to be overlapped with a part of the ceramic carrier 3. In addition, the laser emission chip 4 is also mounted in the ceramic carrier 3. Therefore, the overall structure of the laser emission apparatus is compact, thereby saving a mounting space of the laser emission apparatus. In addition, the heat of the circuit board 5 can also be dissipated through the ceramic carrier 3, thus increasing the heat dissipation speed of the circuit board 5.

Further, because the thermal expansion coefficient of ceramic carrier 3 is smaller than that of the circuit board 5, taking as an example the ceramic carrier 3 made of the aluminum nitride and PCB, the thermal expansion coefficient of the aluminum nitride ceramic carrier 3 is 4.6 ppm/° C., and the thermal expansion coefficient of PCB is 14-17 ppm/° C. The thermal expansion coefficient of ceramic carrier 3 is smaller than that of PCB. Therefore, the ceramic carrier 3 can maintain structural stability and is not easily deformed even when the laser emission chip 4 generates a higher temperature, which in turn can improve the mounting stability of the laser emission apparatus.

In some embodiments, the circuit board 5 is mounted on the bearing surface 71. The circuit board 5 is fixedly connected to the heat dissipation support member 7, so that the heat generated by the circuit board 5 can be discharged through the heat dissipation support member 7. Therefore, the ceramic carrier 3 is only configured to mount the laser emission chip 4. On the basis of the heat dissipation of the laser emission chip 4, the use of ceramic carrier 3 can be reduced to save costs.

In some embodiments, see FIG. 18, the heat dissipation support member 7 includes the metal board 70 and a metal boss 73. The metal board 70 includes a bearing surface 71. The metal boss 73 protrudes and is arranged in the bearing surface 71. The circuit board 5 is mounted on the bearing surface 71 and has the avoiding hole 51 for avoiding the metal boss 73. The metal boss 73 is arranged in avoiding hole 51. The metal boss 73 and the wall of the avoiding hole 51 are arranged at intervals, so that the circuit board 5 can be attached to the bearing surface 71 as a whole and dissipates the heat through the metal board 70. It should be noted that the metal boss 73 can be arranged as a block-shape or a cylindrical shape, etc. Correspondingly, the shape of the avoidance hole 51 can be set as a round shape, a rectangular shape or the like that matches the metal boss 73, so that the metal boss 73 can pass through and be arranged in the avoidance hole 51.

Further, see FIG. 18, the end of the metal boss 73 away from the metal board 70 is flush with or above the surface of the circuit board 5 away from the metal board 70. The ceramic carrier 3 is mounted on the side of the metal boss 73 away from the metal board 70. The laser emission chip 4 is mounted on the side of the ceramic carrier 3 away from the metal boss 73, that is, the laser emission chip 4, the metal boss 73, and the metal board 70 are stacked in order from top to bottom. In this way, the whole of the circuit board 5 can be in contact with the bearing surface 71, so that the heat generated by the circuit board 5 is discharged through the metal board 70. Further, the laser emission chip 4 is in contact with the ceramic carrier 3, the higher thermal conductivity coefficient of the ceramic carrier 3 can be utilized to discharge the heat generated by the ceramic carrier 3 in a timely manner.

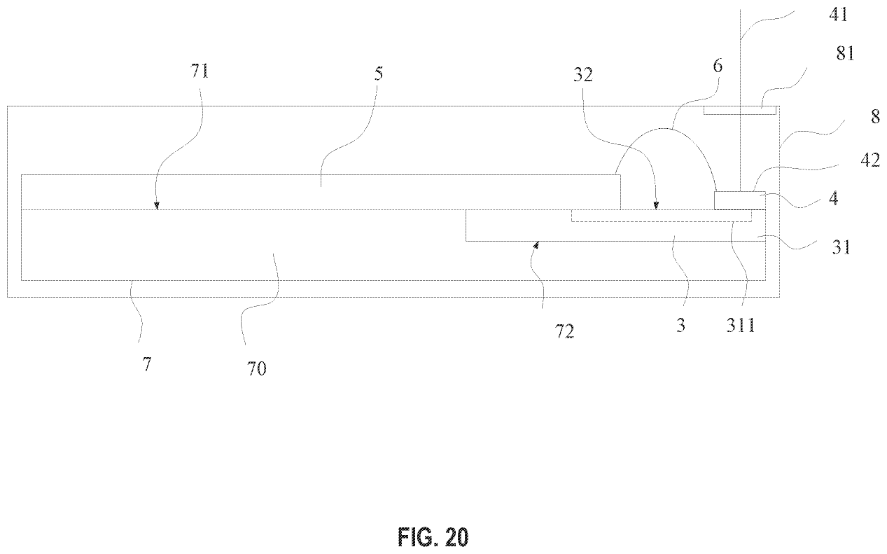

Referring to FIG. 20, a second aspect of this application provides LiDAR, where the LiDAR includes a housing 8 and the laser emission apparatus as described above. The laser emission apparatus is mounted in the housing 8. The housing 8, on the one hand, provides a location for mounting and fixing the laser emission apparatus, and on the other hand, isolates the laser emission apparatus from the outside world to avoid damage to the laser emission apparatus caused by an external factor so as to protect the laser emission apparatus. Further, the housing 8 can be made of copper, iron, polyvinyl chloride (PVC) and other hard materials.

The housing 8 has a light-transmitting region 81 so that the light beam 41 emitted from the laser emission chip 4 is emitted towards the outer side of the housing 8 through the light-transmitting region 81. The light-transmitting region is located on one side of the housing 8 and provided in correspondence with a light-emitting surface 42 of the laser emission chip 4.

In some embodiments, the direction of the light-emitting surface of the laser emission chip 4 differs depending on the type of the laser emission chip 4, for example, when the laser emission chip 4 is a VCSEL (Vertical-Cavity Surface-Emitting Laser Device), the light-emitting direction of the laser emission chip 4 is perpendicular to the light-emitting surface 42 of the laser emission chip 4. When the laser emission chip 4 is an EEL (Edge Emitting Laser Device), the light-emitting direction of the laser emission chip 4 is parallel to or at a certain angle to the light-emitting surface 42 of the laser emission chip 4. The laser emission chip 4 can also be a laser module. The laser module can be swept by a plurality of angles and requires multi-angle light emission. Therefore, the location, size and shape of the light-transmitting region 81 can be set correspondingly according to light-emitting direction. There is no limitation to these embodiments.

It should be noted that the light-transmitting region can be a light-transmitting plastic or a light-transmitting glass, so that the laser beam 41 from the laser emission chip 4 can pass through the light-transmitting region.

The same or similar reference signs in the drawings correspond to the same or similar components. In the description of this application, it should be understood that if terms “upper,” “lower,” “left,” “right,” etc. indicating orientation or positional relationship are based on the orientation or positional relationship shown in the drawings, the terms are only for the convenience of describing the application and simplifying the description, but does not indicate or imply that the device or element should have a specific orientation or is constructed and operated in a specific orientation. Therefore, the terms describing the positional relationship in the drawings are only used for exemplary description, and cannot be understood as a limitation of the patent. For a person skilled in the art, the specific meaning of the forgoing terms can be understood according to the specific circumstances.

The forgoing are only the preferred embodiments of this application and are not intended to limit this application. Any modification, equivalent replacement and improvement made within the spirit and principle of this application shall be included within the protection scope of this application.

What is claimed is:

1. A laser emission module, comprising:
a laser emitter;
a heat conduction substrate comprising a first board surface, wherein the first board surface is connected to the laser emitter; and
a first support board comprising a third board surface facing toward the laser emitter, wherein the third board surface has a mounting region, and the heat conduction substrate corresponding to the mounting region is mounted on the first support board.

2. The laser emission module according to claim 1,
wherein along a direction parallel to the first board surface, a size of the heat conduction substrate is equal to a size of the laser emitter, or
a size of the heat conduction substrate is unequal to a size of the laser emitter, and an absolute value of a difference between the size of the heat conduction substrate and the size of the laser emitter is within a first preset range;
or
wherein along a direction perpendicular to the first board surface, the first board surface is disposed to be flush with the third board surface, or the first board surface and the third board surface are disposed at intervals, and a distance between the first board surface and the third board surface is within a second preset range.

3. The laser emission module according to claim 1, wherein the heat conduction substrate is a ceramic substrate or an aluminum substrate.

4. The laser emission module according to claim 1, further comprising:
a first heat conduction member, wherein the first heat conduction member is viscous, filled between the laser emitter and the first board surface of the heat conduction substrate, and configured to connect the laser emitter to the heat conduction substrate for transmitting heat of the laser emitter to the heat conduction substrate;
or
a first binding member, wherein the first binding member is viscous, disposed around an edge of the laser emitter, and configured to connect the laser emitter to the heat conduction substrate; and
a second heat conduction member, wherein the second heat conduction member is filled between the laser emitter and the heat conduction substrate, at least partially located in space surrounded by the first binding member, and configured to transmit the heat of the laser emitter to the heat conduction substrate.

5. The laser emission module according to claim 4, wherein the laser emission module comprises the first heat conduction member, and the first heat conduction member comprises a silver paste layer filled between the laser emitter and the first board surface of the heat conduction substrate.

6. The laser emission module according to claim 1, wherein the heat conduction substrate further comprises a second board surface relative to the first board surface, and the first support board further comprises a fourth board surface relative to the third board surface; and wherein
the mounting region is a mounting surface disposed on the third board surface, and the second board surface of the heat conduction substrate is attached to the mounting surface; or
the mounting region is concavely provided with a recess in a direction facing toward the fourth board surface, the recess is a blind recess, the second board surface of the heat conduction substrate is attached to a bottom plane of the recess, and at least part of the heat conduction substrate is embedded in the recess; or
the mounting region has a through hole penetrating through the third board surface and the fourth board surface, at least part of the heat conduction substrate is embedded in the through hole, and the second board surface is in one of the following configurations: located inside the through hole, flush with the fourth board surface, or located outside the through hole.

7. The laser emission module according to claim 6, wherein the mounting region has the through hole penetrating through the third board surface and the fourth board surface, at least part of the heat conduction substrate is embedded in the through hole, the second board surface of the heat conduction substrate comes into contact with a heat dissipation structure via a first heat conduction element, the first heat conduction element is configured to transmit heat absorbed by the heat conduction substrate to the heat dissipation structure, and the heat dissipation structure is configured to perform heat dissipation processing on the heat conduction substrate.

8. The laser emission module according to claim 7, wherein
the second board surface is flush with the fourth board surface, and the heat dissipation structure has a plane structure attached to the second board surface on a side facing toward the second board surface; or
the second board surface is located outside the through hole, the heat dissipation structure has a concave structure on a side facing toward the second board surface, and the second board surface extends into the concave structure and comes into contact with an inner wall of the concave structure via the first heat conduction element; or
the second board surface is located inside the through hole, the heat dissipation structure has a convex structure on a side facing toward the second board surface, and the convex structure extends into the through hole and comes into contact with the second board surface via the first heat conduction element.

9. The laser emission module according to claim 7, wherein
the through hole comprises a first sub-hole penetrating through the third board surface and a second sub-hole penetrating through the fourth board surface, the first sub-hole communicates with the second sub-hole, a diameter of the first sub-hole is greater than a diameter of the second sub-hole to form a stepped structure, and the heat conduction substrate is located in the first sub-hole and supported on a stepped surface of the stepped structure; or
the through hole defines a hole axis, the through hole comprises a first hole segment penetrating through the third board surface and a second hole segment penetrating through the fourth board surface, the first hole segment communicates with the second hole segment, and a diameter of the first hole segment is less than a diameter of the second hole segment to form a restrictive structure; the heat conduction substrate comprises a connection portion and a restrictive portion that are laminated, and an outer peripheral side surface of the connection portion is closer to the hole axis than an outer peripheral side surface of the restrictive portion to form an abutment structure that fits the restrictive portion; the connection portion fills at least part of the first hole segment, and the restrictive portion fills at least part of the second hole segment; and the first board surface of the heat conduction substrate is on a side of the connection portion farther away from the restrictive portion, and the second board surface of the heat conduction substrate is on a side of the restrictive portion farther away from the connection portion.

10. A laser emission apparatus, comprising:
a ceramic carrier;
a laser emission chip affixed to the ceramic carrier; and
a circuit board, spaced or partially overlapped with the ceramic carrier and electrically connected to the laser emission chip, to control the laser emission chip to emit a laser beam.

11. The laser emission apparatus according to claim 10, wherein
the circuit board is abutted against and electrically connected to the laser emission chip, to form a laser emission loop; or
the laser emission apparatus further comprises a wire, the ceramic carrier has electrical conductivity, and the circuit board, the wire, the laser emission chip, the ceramic carrier, and the circuit board are electrically connected in sequence to form the laser emission loop; or
the ceramic carrier comprises an insulating substrate, a first electrically conductive part, and a second electrically conductive part, wherein the first electrically conductive part and the second electrically conductive part are mutually insulated, arranged on the insulating substrate, and have electrical conductivities, and wherein the circuit board, the first electrically conductive part, the laser emission chip, the second electrically conductive part, and the circuit board are electrically connected in sequence to form a laser emission loop; or
the laser emission apparatus further comprises a first wire and a second wire, wherein the circuit board, the first wire, the laser emission chip, the second wire, and the circuit board are electrically connected in sequence to form a laser emission loop.

12. The laser emission apparatus according to claim 10, wherein
the ceramic carrier is located on either side of the circuit board to be spaced from the circuit board; or
the circuit board has an avoidance hole, and the ceramic carrier is provided at least partially within the avoidance hole and spaced from a wall of the avoidance hole in order to be spaced from the circuit board.

13. The laser emission apparatus according to claim 10, wherein the ceramic carrier has a mounting surface for mounting the laser emission chip, and the laser emission chip has an orthographic projection on the mounting surface located within the mounting surface.

14. The laser emission apparatus according to claim 10, wherein
the laser emission chip is bonded, welded, or connected by the wire to the ceramic carrier; or
the circuit board is bonded, welded, or connected by the wire to the ceramic carrier.

15. The laser emission apparatus according to claim 10, further comprising:
a heat dissipation support member, wherein the ceramic carrier and the circuit board are both provided on the heat dissipation support member.

16. The laser emission apparatus according to claim 15, wherein the heat dissipation support member comprises a metal board, the metal board comprises a bearing surface, the bearing surface is opened and provided with a mounting groove, the circuit board is at least partially mounted on the bearing surface, the ceramic carrier is provided in the mounting groove, and the laser emission chip is mounted on a surface of the ceramic carrier away from a bottom of the mounting groove.

17. The laser emission apparatus according to claim 16, wherein the ceramic carrier is in a board shape, the board-shaped ceramic carrier is arranged behind the mounting groove and flush with the bearing surface, the circuit board is partially pressed and provided on the ceramic carrier to be partially overlapped with the ceramic carrier.

18. The laser emission apparatus according to claim 15, wherein the heat dissipation support member comprises a metal board and a metal boss, the metal board comprises a bearing surface, the metal boss is convexly provided on the bearing surface, the circuit board is mounted on the bearing surface and has an avoidance hole for avoiding the metal boss, the metal boss is provided in the avoidance hole and spaced from a wall of the avoidance hole, and an end of the metal boss away from the bearing surface is flush with or above a surface of the circuit board away from the metal board.
